(19) United States
(12) Patent Application Publication
(10) Pub. No.: US 2025/0311461 A1
(43) Pub. Date: Oct. 2, 2025

(54) IMAGE SENSOR AND METHOD FOR FABRICATING THE SAME

(71) Applicant: SAMSUNG ELECTRONICS CO., LTD., SUWON-SI (KR)

(72) Inventors: Seung Hwi YOO, Suwon-si (KR); Kook Tae KIM, Suwon-si (KR); Seo Yeon PARK, Suwon-si (KR); Jin Gyun KIM, Suwon-si (KR)

(21) Appl. No.: 18/968,928

(22) Filed: Dec. 4, 2024

(30) Foreign Application Priority Data
Mar. 28, 2024 (KR) 10-2024-0042576

(51) Int. Cl. H01L 27/146

(52) U.S. Cl. CPC H10F 39/807; H10F 39/011; H10F 39/182

(57) ABSTRACT

A CMOS type image sensor includes a substrate that includes a first side and a second side that are opposite to each other, a pixel isolation pattern that defines a plurality of unit pixels that are two-dimensionally arranged inside the substrate, and a photoelectric conversion region inside each of the unit pixels. The pixel isolation pattern includes a first insulating film, a first material film, a second insulating film, a second material film, and a gap fill conductive film that are sequentially stacked on an inner wall of the substrate. One end of the first material film adjacent to the first side and one end of the second material film adjacent to the first side are each in contact with the gap fill conductive film, and the first material film and the second material film include a different material from the first insulating film and the second insulating film.

This application claims priority under 35 U.S.C. 119 from Korean Patent Application No. 10-2024-0042576, filed on Mar. 28, 2024 in the Korean Intellectual Property Office, the contents of which are herein incorporated by reference in their entirety.

### TECHNICAL FIELD

Embodiments of the present inventive concept are directed to an image sensor and a method for fabricating the same. More specifically, embodiments of the present inventive concept are directed to a CMOS type image sensor that includes a pixel isolation pattern and a method for fabricating the same.

### DISCUSSION OF THE RELATED ART

An image sensing device is a semiconductor element that converts optical information into an electric signal. Such an image sensing device may include a charge coupled device (CCD) image sensor or a CMOS type (complementary metal-oxide semiconductor) image sensor.

The image sensor may be configured in the form of a package, and the package may have a structure that protects the image sensor and allows light to enter a photo-receiving surface or sensing area of the image sensor.

### SUMMARY

Embodiments of the present inventive concept provide an image sensor that has increased performance and yield.

Embodiments of the present inventive concept also provide a method for fabricating an image sensor that has increased performance and yield.

However, embodiments of the present inventive concept are not restricted to those set forth herein. The above and other features of the present inventive concept will become more apparent to one of ordinary skill in the art to which the present inventive concept pertains by referencing the detailed description of the present inventive concept given below.

According to an embodiment of the present inventive concept, there is provided an image sensor that includes a substrate that includes a first side and a second side that are opposite to each other, a pixel isolation pattern that defines a plurality of unit pixels that are two-dimensionally arranged inside the substrate, and a photoelectric conversion region inside each of the unit pixels. The pixel isolation pattern includes a first insulating film, a first material film, a second insulating film, a second material film, and a gap fill conductive film that are sequentially stacked on an inner wall of the substrate. One end of the first material film adjacent to the first side and one end of the second material film adjacent to the first side are each in contact with the gap fill conductive film, and the first material film and the second material film include a different material from the first insulating film and the second insulating film.

According to an embodiment of the present inventive concept, there is provided an image sensor that includes a substrate, a pixel isolation trench that defines a plurality of unit pixels that are two-dimensionally arranged inside the substrate, a photoelectric conversion region inside each of the unit pixels, and a pixel isolation pattern that at least partially fills the pixel isolation trench. The pixel isolation trench includes a first trench that has a first width, and a second trench that has a second width greater than the first width. A first portion of the pixel isolation pattern includes a first insulating film, a first material film, a second insulating film, a second material film, and a gap fill insulating film that are sequentially stacked on an inner wall of the first trench. A second portion of the pixel isolation pattern includes the first insulating film, the first material film, the second insulating film, the second material film, and a gap fill conductive film that are sequentially stacked on an inner wall of the second trench, and the first material film and the second material film include a different material from the first insulating film and the second insulating film.

According to an embodiment of the present inventive concept, there is provided an image sensor that includes a substrate, a pixel isolation pattern that defines a plurality of unit pixels that are two-dimensionally arranged inside the substrate, and a photoelectric conversion region inside each of the unit pixels. The plurality of unit pixels include a first unit pixel, a second unit pixel adjacent to the first unit pixel in a first direction, and a third unit pixel adjacent to the second unit pixel in a second direction that crosses the first direction. The pixel isolation pattern includes a first portion disposed between the first unit pixel and the second unit pixel, and a second portion disposed between the first unit pixel and the third unit pixel. The first portion of the pixel isolation pattern includes a first insulating film, a first material film, a second insulating film, a second material film, and a gap fill insulating film that are sequentially stacked on an inner wall of the substrate. The second portion of the pixel isolation pattern includes the first insulating film, the first material film, the second insulating film, the second material film, and a gap fill conductive film that are sequentially stacked on the inner wall of the substrate, at least one of the first material film or the second material film is conductive.

### BRIEF DESCRIPTION OF THE DRAWINGS

FIG. 1 is a block diagram of an image sensor according to some embodiments.

FIG. 2 is a circuit diagram of an image sensor according to some embodiments.

FIG. 3 is a plan view of a pixel array of an image sensor according to some embodiments.

FIG. 4 is a schematic cross-sectional view taken along line A-A of FIG. 3.

FIG. 5 is a schematic cross-sectional view taken along line B-B of FIG. 3.

FIGS. 6A to 6H are enlarged views of a region S1 of FIG. 4 and a region S2 of FIG. 5.

FIG. 7 is a plan view of a pixel array of an image sensor according to some embodiments.

FIG. 8 is a schematic cross-sectional view taken along line C-C of FIG. 7.

FIG. 9 is a schematic layout diagram of an image sensor according to some embodiments.

FIG. 10 is a schematic cross-sectional view of an image sensor of FIG. 9.

FIGS. 11 to 33 are intermediate stage diagrams that illustrate a method for fabricating an image sensor according to some embodiments.

### DETAILED DESCRIPTION

In this specification, when a first component is described as being in contact with a second component, the first component is in direct contact with the second component.

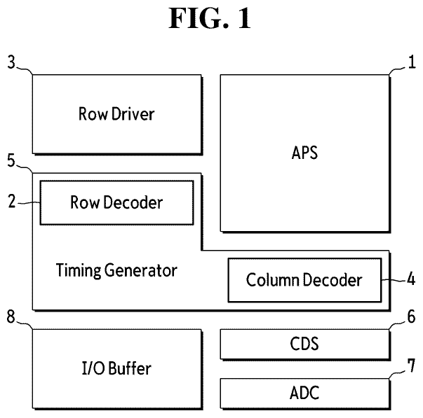

An image sensor according to exemplary embodiments will be described below with reference to FIGS. 1 to 10.

FIG. 1 is a block diagram of an image sensor according to some embodiments.

Referring to FIG. 1, an image sensor according to some embodiments includes an active pixel sensor array (APS) 1, a row decoder 2, a row driver 3, a column decoder 4, a timing generator 5, a correlated double sampler 6, an analog-to-digital converter (ADC) 7, and an I/O buffer 8.

The active pixel sensor array 1 includes a plurality of unit pixels that are two-dimensionally arranged and convert optical signals into electrical signals. The active pixel sensor array 1 is driven by a plurality of driving signals from the row driver 3, such as a pixel selection signal, a reset signal, and a charge transfer signal. Furthermore, the electrical signals converted by the active pixel sensor array 1 are provided to the correlated double sampler 6.

The row driver 3 provides the active pixel sensor array 1 with a plurality of driving signals that drive a plurality of unit pixels according to results decoded by the row decoder 2. When unit pixels are arranged in the form of a matrix, a driving signal is provided for each row.

The timing generator 5 provides a timing signal and a control signal to the row decoder 2 and the column decoder 4.

The correlated double sampler (CDS) 6 receives, holds and samples the electrical signals generated by the active pixel sensor array 1. The correlated double sampler 6 doubly samples a specific noise level and a signal level due to an electric signal, and outputs a difference level that corresponds to a difference between the noise level and the signal level.

The analog-to-digital converter (ADC) 7 converts an analog signal that corresponds to the difference level output from the correlated double sampler 6 into a digital signal and outputs the digital signal.

The I/O buffer 8 latches the digital signal, and the latched signal sequentially outputs the digital signal to a video signal processing unit according to the decoding result from the column decoder 4.

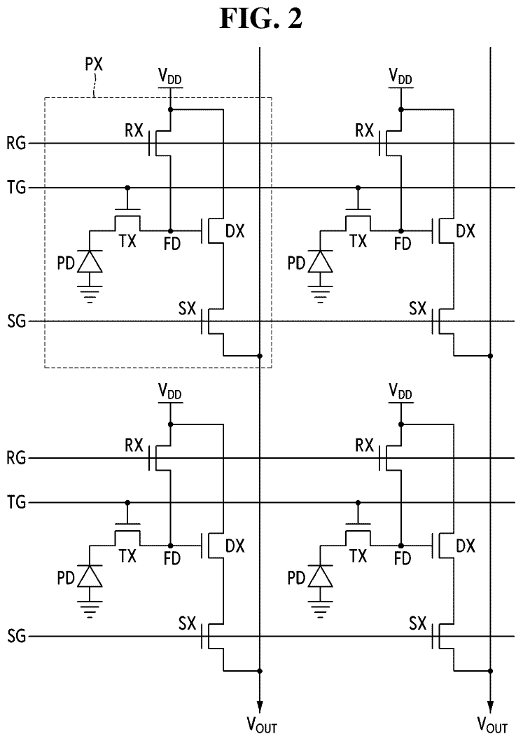

FIG. 2 is a circuit diagram of an image sensor according to some embodiments.

Referring to FIG. 2, an image sensor according to some embodiments includes a plurality of unit pixels PX.

The plurality of unit pixels PX are two-dimensionally arranged, such as in the form of a matrix. Each unit pixel PX includes a photoelectric conversion element PD, a transfer transistor TX, a floating diffusion region FD, a reset transistor RX, a drive transistor DX, and a selection transistor SX.

The photoelectric conversion element PD generates electric charges in proportion to the amount of light that is externally incident. The photoelectric conversion element PD is coupled to the transfer transistor TX that transmits the generated and accumulated electric charges to the floating diffusion region FD. Because the floating diffusion region FD switches electric charges to voltage and has a parasitic capacitance, the electric charges are accumulatively stored.

One end of the transfer transistor TX is connected to the photoelectric conversion element PD, and the other end of the transfer transistor TX is connected to the floating diffusion region FD. The transfer transistor TX is driven by a predetermined bias, such as a transfer signal TG. For example, the transfer transistor TX transmits the electric charges received from the photoelectric conversion clement PD to the floating diffusion region FD according to the transfer signal TG.

The drive transistor DX is a source follower buffer amplifier. The drive transistor DX amplifies a change in the electric potential of the floating diffusion region FD that has received the electric charge from the photoelectric conversion element PD, and outputs the amplified change to an output line V_{OUT}. When the drive transistor DX is turned on, a predetermined electrical potential, such as a power supply voltage V_{DD} provided to a drain of the drive transistor DX, is transmitted to a drain region of the selection transistor SX.

The selection transistor SEL selects a row of unit pixels PX to be read. The selection transistor SEL is driven by a selection line that applies a predetermined bias, such as a row selection signal SG.

The reset transistor RX periodically resets the floating diffusion region FD. The reset transistor RX is driven by a reset line that applies a predetermined bias, such as a reset signal RG. When the reset transistor RX is turned on by the reset signal RG, a predetermined electrical potential provided to the drain of the reset transistor RX, such as the power supply voltage V_{DD}, is transmitted to the floating diffusion region FD to reset the floating diffusion region FD.

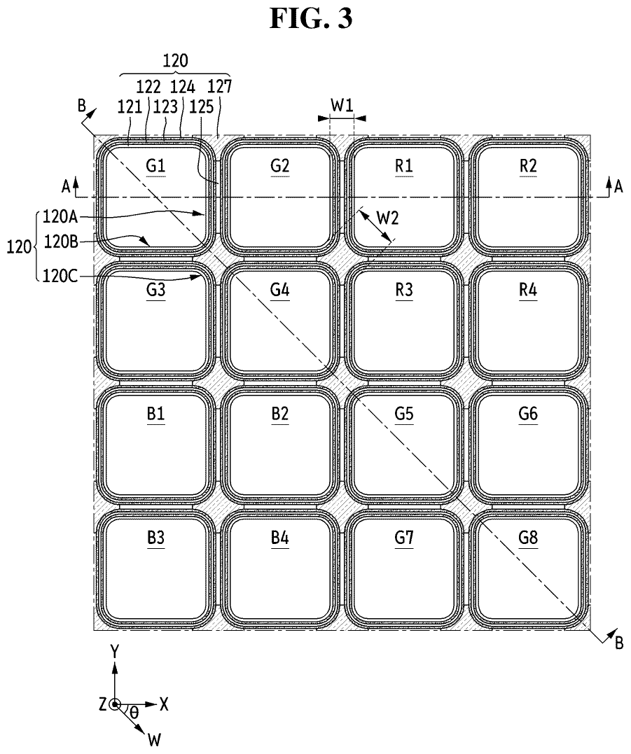

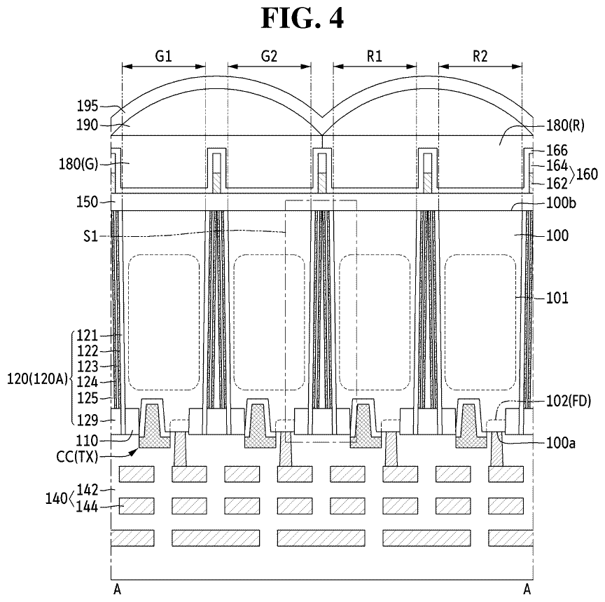

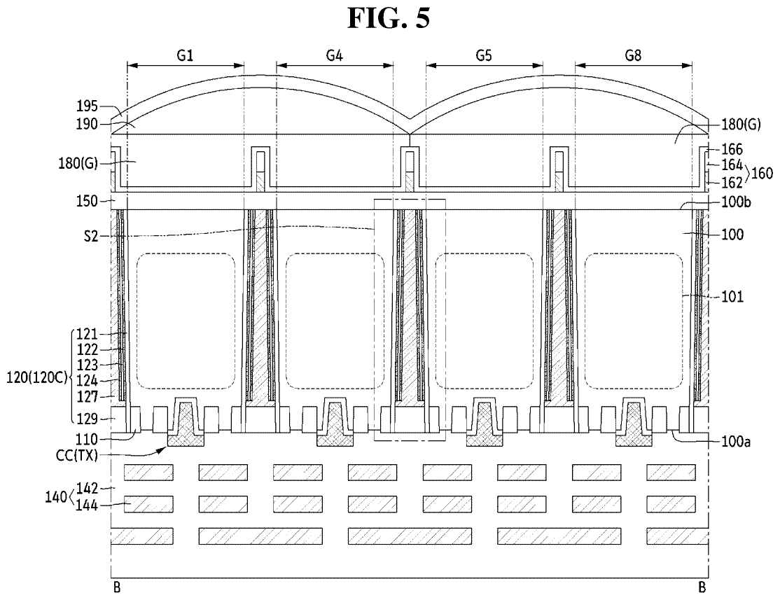

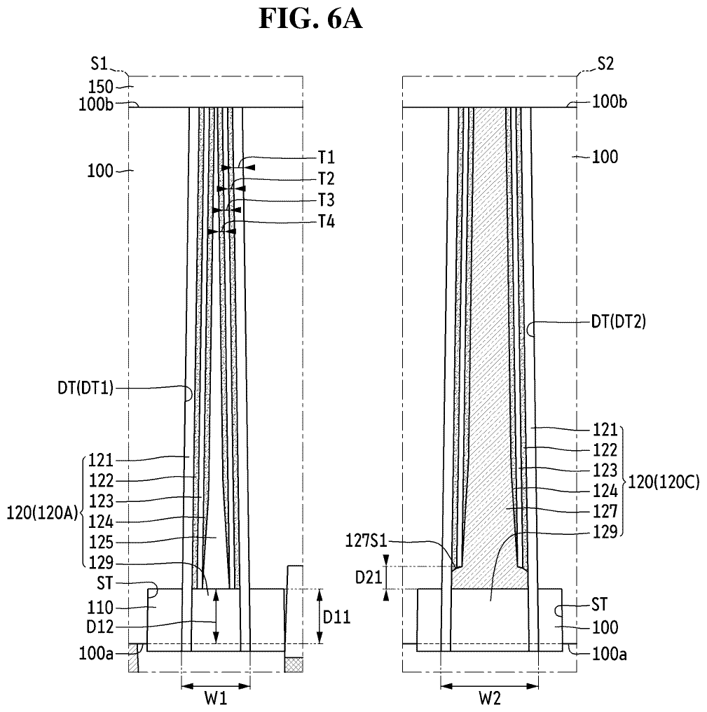

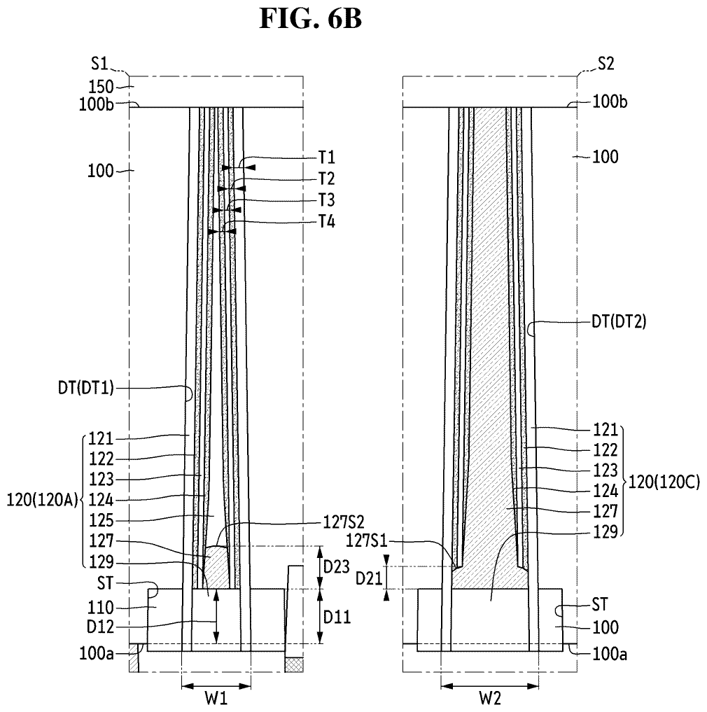

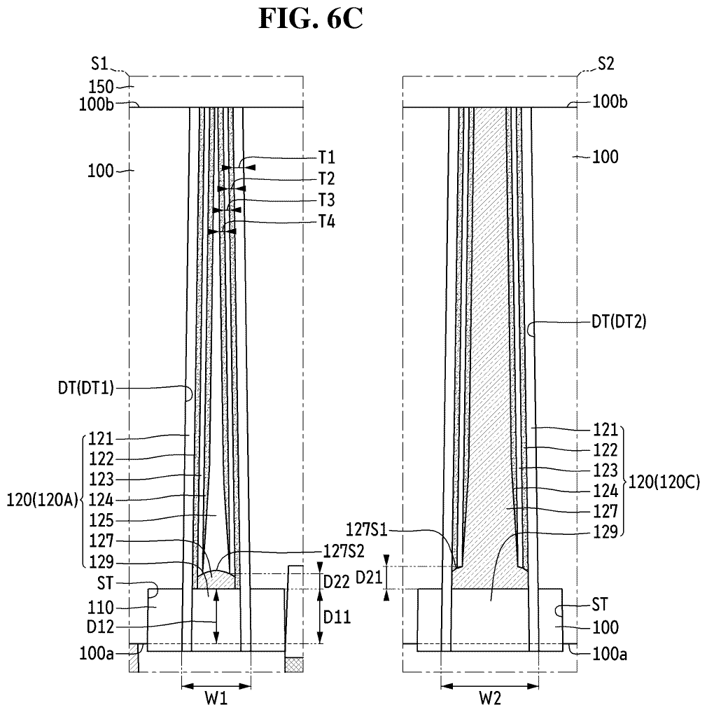

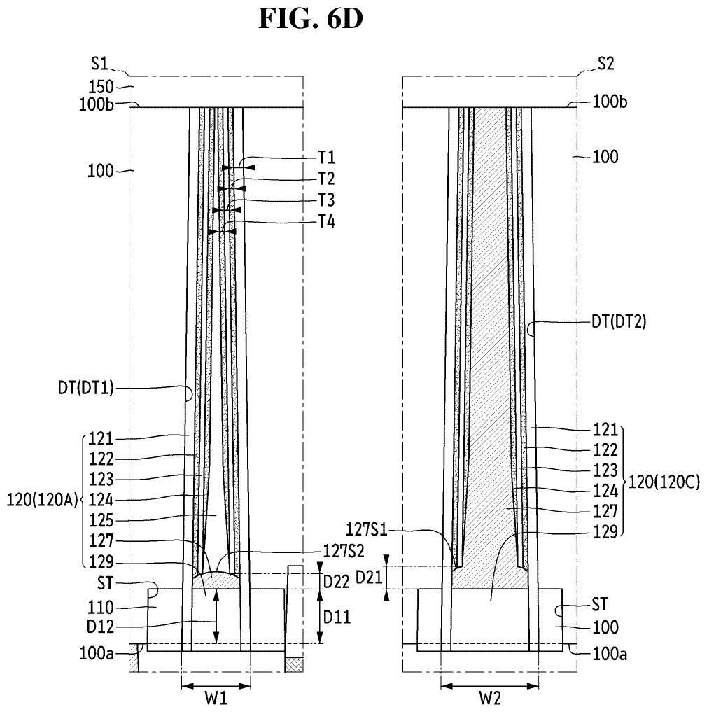

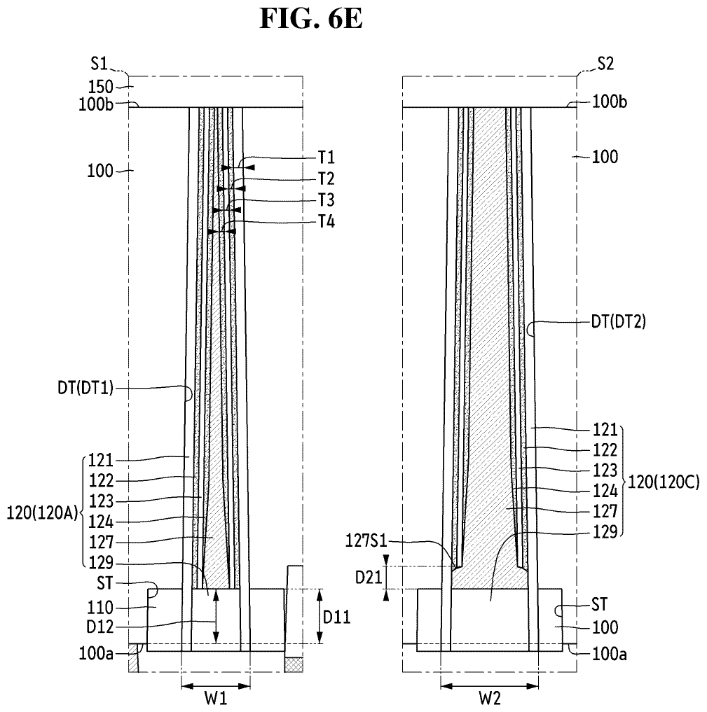

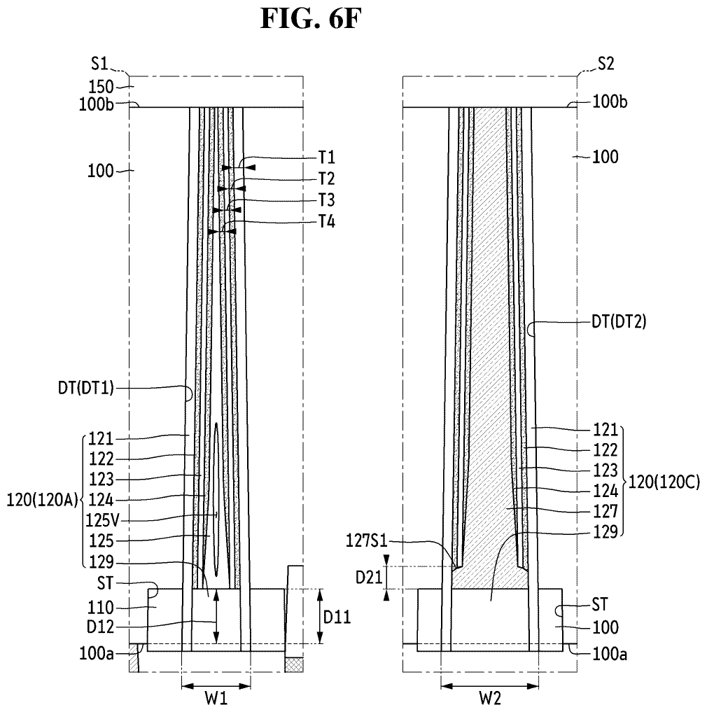

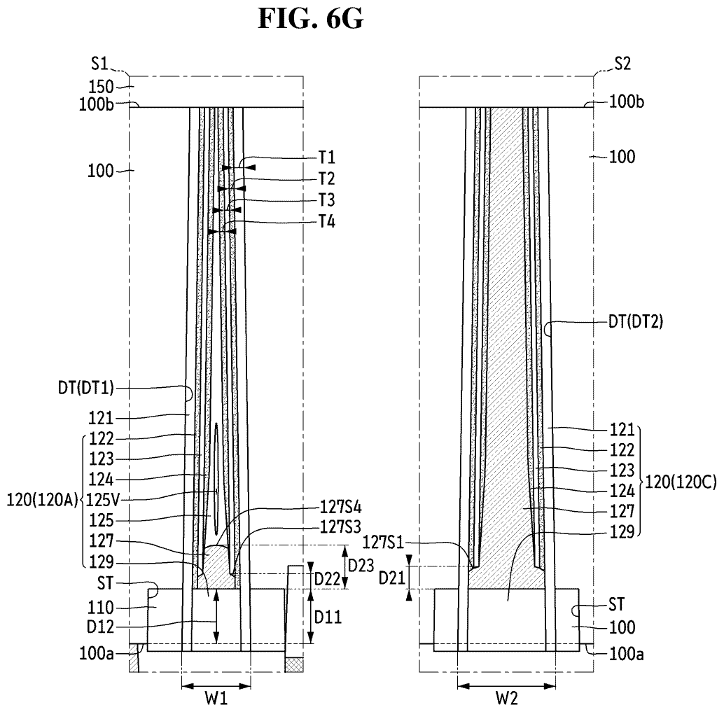

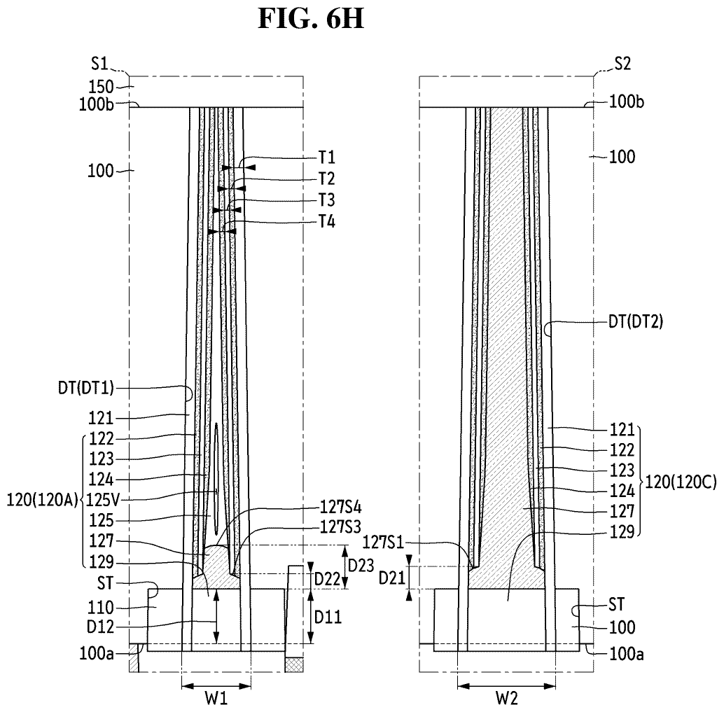

FIG. 3 is a plan view of a pixel array of an image sensor according to some embodiments. FIG. 4 is a schematic cross-sectional view taken along line A-A of FIG. 3. FIG. 5 is a schematic cross-sectional view taken along line B-B of FIG. 3. FIGS. 6A to 6H are enlarged views of a region S1 of FIG. 4 and a region S2 of FIG. 5.

Referring to FIGS. 3 to 6A, an image sensor according to some embodiments includes a first substrate 100, a photoelectric conversion region 101, an element isolation pattern 110, a pixel isolation pattern 120, a first circuit element CC, a first wiring structure 140, a surface insulating film 150, a grid pattern 160, a color filter 180, and a micro lens 190.

The first substrate 100 is a semiconductor substrate. For example, the first substrate 100 may be bulk silicon or SOI (silicon-on-insulator). The first substrate 100 may be a silicon substrate, or may include other materials, such as at least one of silicon germanium, indium antimonide, lead tellurium compound, indium arsenic, indium phosphide, gallium arsenide or gallium antimonide. In some embodiments, the first substrate 100 has an epitaxial layer formed on a base substrate.

The first substrate 100 includes a first side 100a and a second side 100b that are opposite to each other. In embodiments described below, the first side 100a may be referred to as a front side of the first substrate 100, and the second side 100b may be referred to as a back side of the first substrate 100. In some embodiments, the second side 100b of the first substrate 100 is a photo-receiving surface to which light is incident. For example, the image sensor according to some embodiments is a back-illuminated (BSI) image sensor.

In some embodiments, the first substrate 100 includes impurities of a first conductivity type. In embodiments to be described below, although the first conductivity type is disclosed as a p-type, embodiments are not necessarily limited thereto, and in other embodiments, the first conductivity type is an n-type.

A plurality of unit pixels G1 to G8, R1 to R4, and B1 to B4 are formed inside the first substrate 100. The plurality of unit pixels G1 to G8, R1 to R4, and B1 to B4 are two-dimensionally arranged, such as in the form of a matrix, along a horizontal plane, such as an XY plane that includes a first direction X and a second direction Y.

In some embodiments, the plurality of unit pixels G1 to G8, R1 to R4, and B1 to B4 form a plurality of pixel groups. For example, a first pixel group G1 to G4, a second pixel group R1 to R4, a third pixel group B1 to B4, and a fourth pixel group G5 to G8, which are adjacent to each other, are formed in the first substrate 100. The second pixel groups R1 to R4 is adjacent to the first pixel groups G1 to G4 in the first direction X. The third pixel groups B1 to B4 is adjacent to the first pixel groups G1 to G4 in the second direction Y that crosses or is perpendicular to the first direction X. The fourth pixel groups G5 to G8 are adjacent to the second pixel groups R1 to R4 in the second direction Y, and are adjacent to the third pixel groups B1 to B4 in the first direction X. For example, the fourth pixel groups G5 to G8 are adjacent to the first pixel groups G1 to G4 in a diagonal direction between the first direction X and the second direction Y, hereinafter referred to as a third direction W. For example, an acute angle θ between the first direction X and the third direction W is about 45°.

Each pixel group includes two or more unit pixels of the plurality of unit pixels G1 to G8, R1 to R4, and B1 to B4. For example, the first pixel groups G1 to G4 includes a first unit pixel G1, a second unit pixel G2, a third unit pixel G3, and a fourth unit pixel G4 that are adjacent to each other. The second unit pixel G2 is adjacent to the first unit pixel G1 in the first direction X. The third unit pixel G3 is adjacent to the first unit pixel G1 in the second direction Y. The fourth unit pixel G4 is adjacent to the second unit pixel G2 in the second direction Y, and is adjacent to the third unit pixel G3 in the first direction X. For example, the fourth unit pixel G4 is adjacent to the first unit pixel G1 in the third direction W.

The photoelectric conversion region 101 is formed inside the first substrate 100. The photoelectric conversion region 101 is formed in each of the unit pixels G1 to G8, R1 to R4, and B1 to B4 inside the first substrate 100. For example, a plurality of photoelectric conversion regions 101 that correspond to the plurality of unit pixels G1 to G8, R1 to R4, and B1 to B4 arc two-dimensionally arranged, such as in the form of a matrix, inside the first substrate 100.

The photoelectric conversion region 101 and the surrounding region of the first substrate 100 form the photoelectric conversion clement PD of FIG. 2. For example, the photoelectric conversion region 101 generates charges in proportion to an amount of externally incident light. For example, the photoelectric conversion element PD formed by the photoelectric conversion region 101 includes, but not limited to, at least one of a photo diode, a photo transistor, a photo gate, a pinned photo diode (PPD) or a combination thereof.

The photoelectric conversion region 101 has a second conductivity type that differs from the first conductivity type. For example, the photoelectric conversion region 101 can be formed by ion-implanting n-type impurities into the p-type first substrate 100.

The element isolation pattern 110 is formed inside the first substrate 100. The element isolation pattern 110 is adjacent to or in contact with the first side 100a of the first substrate 100. The element isolation pattern 110 defines an active region inside the first substrate 100 that includes the first side 100a of the first substrate 100. For example, an element isolation trench ST that extends from the first side 100a and defines an active region of the first substrate 100 is formed in the first substrate 100. The element isolation pattern 110 fills at least a part of the element isolation trench ST.

The element isolation pattern 110 includes an insulating material, such as, but not limited to, at least one of silicon oxide, silicon nitride, silicon oxynitride or a combination thereof. For example, the element isolation pattern 110 includes a silicon oxide film. Although the element isolation pattern 110 is shown as being only a single film, embodiments are not necessarily limited thereto, and in other embodiments, the first insulating film 121 includes multiple films.

The active region of the first substrate 100 defined by the element isolation pattern 110 includes an impurity region 102. The impurity region 102 has the second conductivity type. For example, the impurity region 102 can be formed by ion-implantation of an n-type impurity into the p-type first substrate 100. At least some of the plurality of unit pixels G1 to G8, R1 to R4, and B1 to B4 include the impurity region 102 provided as the floating diffusion region FD of FIG. 2.

In some embodiments, a part of the element isolation pattern 110 protrudes from the first side 100a of the first substrate 100. For example, as shown in FIGS. 4 and 5, a lower part of the element isolation pattern 110 protrudes downward from the first side 100a of the first substrate 100.

The pixel isolation pattern 120 is formed inside the first substrate 100. The pixel isolation pattern 120 defines the plurality of unit pixels G1 to G8, R1 to R4, and B1 to B4 in the first substrate 100. For example, a pixel isolation trench DT that defines the plurality of unit pixels G1 to G8, R1 to R4, and B1 to B4 of the first substrate 100 is formed inside the first substrate 100 and the element isolation pattern 110. The pixel isolation trench DT is formed, for example, in a lattice shape in a plan view in the XY plane and surrounds each of the unit pixels G1 to G8, R1 to R4, and B1 to B4. The pixel isolation pattern 120 fills at least a part of the pixel isolation trench DT.

In some embodiments, the width of the pixel isolation trench DT decreases from the first side 100a of the first substrate 100 toward the second side 100b of the first substrate 100. The width is measured along a horizontal direction, such as the first direction X, the second direction Y, or the third direction W. This results from an etching process that forms the pixel isolation trench DT that is performed toward the first side 100a of the first substrate 100. For example, the pixel isolation pattern 120 is an FDTI (Frontside DTI) formed by a DTI (Deep Trench Isolation) process on the first side 100a of the first substrate 100.

In some embodiments, the pixel isolation trench DT completely penetrates the first substrate 100. For example, the pixel isolation trench DT is adjacent to or in contact with the second side 100b of the first substrate 100.

The pixel isolation pattern 120 prevents photocharges generated in a specific unit pixel, such as the first unit pixel G1, from moving to adjacent unit pixels, such as second to fourth unit pixels G2 to G4, due to a random drift. Furthermore, the pixel isolation pattern 120 prevents optical cross-talk in which light incident on a specific unit pixel, such as the first unit pixel G1, is incident on adjacent unit pixels, such as the second to fourth unit pixels G2 to G4.

In some embodiments, the pixel isolation pattern 120 includes a first portion 120A, a second portion 120B, and a third portion 120C that are connected to each other in a plan view. The first portion 120A extends in the second direction Y and separates unit pixels, such as the first unit pixel G1 and the second unit pixel G2, that are adjacent in the first direction X. The second portion 120B extends in the first direction X, and separate unit pixels, such as the first unit pixel G1 and the third unit pixel G3, that are adjacent in the second direction Y. The third portion 120C is disposed in a region in which the first portion 120A and the second portion 120B intersect. The third portion 120C connects the first portion 120A to the second portion 120B. The third portion 120C separates unit pixels, such as the first unit pixel G1 and the fourth unit pixel G4, or the second unit pixel G2 and the third unit pixel G3, that are adjacent in the third direction W.

In some embodiments, a width of the third portion 120C is greater than a width of the first portion 120A and/or a width of the second portion 120B. For example, the pixel isolation trench DT includes a first trench DT1 that has a first width W1, and a second trench DT2 that has a second width W2 greater than the first width W1. The first width W1 and the second width W2 are measured along a horizontal direction, such as the first direction X, the second direction Y or the third direction, at the same height in the vertical direction, hereinafter referred to as a fourth direction Z. For example, the second width W2 in the third direction W is greater than the first width W1 in the first direction X at the first side 100a of the first substrate 100. The first portion 120A and/or the second portion 120B of the pixel isolation pattern 120 fills at least a part of the first trench TD1 of the pixel isolation trench DT, and the third portion 120C of the pixel isolation pattern 120 fills at least a part of the second trench DT2 of the pixel isolation trench DT.

The pixel isolation pattern 120 includes a first insulating film 121, a first material film 122, a second insulating film 123, a second material film 124, a gap fill insulating film 125, a gap fill conductive film 127, and a buried insulating film 129.

The first insulating film 121, the first material film 122, the second insulating film 123, and the second material film 124 are sequentially stacked on the inner wall of the first substrate 100. The gap fill insulating film 125 and the gap fill conductive film 127 are stacked on the second material film 124. The gap fill insulating film 125 and the gap fill conductive film 127 fill at least a part of the region of the pixel isolation trench DT that remains after being filled with the first insulating film 121, the first material film 122, the second insulating film 123, and the second material film 124. The buried insulating film 129 is stacked on the first insulating film 121, the first material film 122, the second insulating film 123, the second material film 124, the gap fill insulating film 125, and the gap fill conductive film 127. At least a part of the buried insulating film 129 is formed inside the element isolation pattern 110.

The first insulating film 121 is in contact with the first substrate 100. The first insulating film 121 is interposed between the first substrate 100 and the first material film 122. In some embodiments, a part of the first insulating film 121 is formed inside the element isolation pattern 110. For example, a part of the first insulating film 121 is in contact with an inner wall of the clement isolation pattern 110. Although is the figures show that there is a boundary between the clement isolation pattern 110 and the first insulating film 121, embodiments are not necessarily limited thereto, and in other embodiments, there is no boundary between the clement isolation pattern 110 and the first insulating film 121. For example, when the clement isolation pattern 110 and the first insulating film 121 include the same material, such as a silicon oxide film, there is no boundary between the clement isolation pattern 110 and the first insulating film 121.

The first insulating film 121 conformally extends along the profile of the inner wall of the pixel isolation trench DT. A thickness T1 of the first insulating film 121 is, for example, from about 1 Å to about 500 Å, or from about 30 Å to about 350 Å.

The first insulating film 121 includes an insulating material, for example, but not limited to, at least one of silicon oxide, silicon nitride, silicon oxynitride, silicon carbonitride, silicon oxycarbonitride or a combination thereof. For example, the first insulating film 121 includes a silicon oxide film. Although the first insulating film 121 is shown to be only a single film, embodiments are not necessarily limited thereto, and in other embodiments, the first insulating film 121 includes multiple films.

The first material film 122 is in contact with the first insulating film 121. The first material film 122 is interposed between the first insulating film 121 and the second insulating film 123. In some embodiments, the first material film 122 is not formed inside the element isolation pattern 110. For example, the first material film 122 is not interposed between the first insulating film 121 and the buried insulating film 129.

The first material film 122 conformally extends along the profile of the inner wall of the first insulating film 121. The thickness T2 of the first material film 122 is, for example, from about 1 Å to about 500 Å, or from about 10 Å to about 350 Å.

The first material film 122 includes a different material from those of the first insulating film 121 and/or the second insulating film 123. For example, when the first insulating film 121 includes a silicon oxide film, the first material film 122 includes, but is not necessarily limited to, at least one of an insulating film such as a silicon nitride film, a silicon carbonitride film, a silicon oxycarbonitride film, a silicon boron nitride film, or a silicon boron carbonitride film; a semiconductor film such as a polysilicon film; or a conductive film such as a polysilicon film doped with impurities or a metal film.

In some embodiments, the first material film 122 is conductive. For example, the first material film 122 includes a polysilicon film doped with a p-type impurity, such as boron (B), or an n-type impurity, such as phosphorus (P). The concentration of impurities doped into the first material film 122 is, for example, from about 5E19 cm⁻³ to about 5E22 cm⁻³.

The second insulating film 123 is in contact with the first material film 122. The second insulating film 123 is interposed between the first material film 122 and the second material film 124. In some embodiments, the second insulating film 123 is not formed inside the element isolation pattern 110. For example, the second insulating film 123 is not interposed between the first insulating film 121 and the buried insulating film 129.

The second insulating film 123 conformally extends along the profile of the inner wall of the first material film 122. A thickness T3 of the second insulating film 123 is, for example, from about 1 Å to about 500 Å, or from about 30 Å to about 350 Å.

The second insulating film 123 includes an insulating material, such as, but not necessarily limited to, at least one of silicon oxide, silicon nitride, silicon oxynitride, silicon carbonitride, silicon oxycarbonitride or a combination thereof. For example, the second insulating film 123 includes a silicon oxide film. In some embodiments, the second insulating film 123 includes, but is not necessarily limited to, at least one of FCVD oxide (Flowable Chemical Vapor Deposition Flowable Oxide), TOSZ (TOnen SilaZenc), HDP oxide (High Density Plasma Oxide) or TEOS (TetraEthylOrthoSilicate).

In some embodiments, the second insulating film 123 includes a low refractive index material that has a lower refractive index than silicon (Si). For example, the second insulating film 123 includes, but is not necessarily limited to, at least one of silicon oxide, aluminum oxide, tantalum oxide, or a combination thereof. The second insulating film 123 increases the light collection efficiency of each of the unit pixels G1 to G8, R1 to R4, and B1 to B4, by refracting or reflecting light obliquely incident on the second side 100b, which is a photo-receiving surface.

The second material film 124 is in contact with the second insulating film 123. The second material film 124 is interposed between the second insulating film 123 and the gap fill insulating film 125, and between the second insulating film 123 and the gap fill conductive film 127. In some embodiments, the second material film 124 is not formed inside the element isolation pattern 110. For example, the second material film 124 is not interposed between the first insulating film 121 and the buried insulating film 129.

The second material film 124 extends along an inner wall of the second insulating film 123. A thickness T4 of the second material film 124 is, for example, from about 1 Å to about 500 Å, or from about 10 Å to about 350 Å. In some embodiments, the thickness T4 of the second material film 124 decreases from the second side 100b of the first substrate 100 toward the first side 100a of the first substrate 100. For example, the thickness T4 of the second material film 124 adjacent to the first side 100a of the first substrate 100 is less than the thickness T4 of the second material film 124 adjacent to the second side 100b of the first substrate 100.

The second material film 124 includes a different material from the first insulating film 121 and/or the second insulating film 123. For example, when the second insulating film 123 includes a silicon oxide film, the second material film 124 includes, but is not necessarily limited to, at least one of an insulating film such as a silicon nitride film, a silicon carbonitride film, a silicon oxycarbonitride film, a silicon boron nitride film, or a silicon boron carbonitride film; a semiconductor film such as a polysilicon film; or a conductive film such as a polysilicon film doped with impurities or a metal film.

In some embodiments, the second material film 124 is conductive. For example, the second material film 124 includes a polysilicon film doped with a p-type impurity such as boron (B), or an n-type impurity such as phosphorus (P). The concentration of impurities doped into the second material film 124 is, for example, from about 5E19 cm⁻³ to about 5E22 cm⁻³.

In some embodiments, the first material film 122 and the second material film 124 include the same material. For example, the first material film 122 and the second material film 124 each include a polysilicon film doped with impurities.

In some embodiments, the first material film 122 and the second material film 124 include different materials from each other. For example, the first material film 122 includes a silicon nitride film, and the second material film 124 includes a polysilicon film doped with impurities.

The gap fill insulating film 125 and the gap fill conductive film 127 are each in contact with the second material film 124. In some embodiments, the width of each of the gap fill insulating film 125 and the gap fill conductive film 127 decreases from the first side 100a of the first substrate 100 toward the second side 100b of the first substrate 100.

The gap fill insulating film 125 includes an insulating material, such as, but not limited to, at least one of silicon oxide, silicon nitride, silicon oxynitride, silicon carbonitride, silicon oxycarbonitride or a combination thereof. For example, the gap fill insulating film 125 includes a silicon oxide film. In some embodiments, the gap fill insulating film 125 includes, but is not necessarily limited to, at least one of FCVD oxide (Flowable Chemical Vapor Deposition Flowable Oxide), TOSZ (TOnen SilaZene), HDP oxide (High Density Plasma Oxide) or TEOS (TetraEthylOrthoSilicate).

In some embodiments, the gap fill insulating film 125 includes a low refractive index material that has a lower refractive index than silicon (Si). For example, the gap fill insulating film 125 includes, but is not necessarily limited to, at least one of silicon oxide, aluminum oxide, tantalum oxide, or a combination thereof. The gap fill insulating film 125 increases the light collection efficiency of each of the unit pixels G1 to G8, R1 to R4, and B1 to B4, by refracting or reflecting light obliquely incident on the second side 100b, which is a photo-receiving surface.

In some embodiments, the second insulating film 123 and the gap fill insulating film 125 include the same material. For example, the second insulating film 123 and the gap fill insulating film 125 each include a silicon oxide film.

The gap fill conductive film 127 includes a conductive material, such as, but not necessarily limited to, at least one of an undoped polysilicon film, an undoped silicon germanium film, an impurity-doped polysilicon film, an impurity-doped silicon germanium film or a metal film. For example, the gap fill conductive film 127 includes a polysilicon film doped with a p-type impurity, such as boron (B), or an n-type impurity, such as phosphorus (P).

In some embodiments, a negative (−) bias voltage is applied to the gap fill conductive film 127. Such a gap fill conductive film 127 can capture holes that may be present on the surface of the first substrate 100 adjacent to the pixel isolation pattern 120, thereby improving dark current characteristics of the image sensor.

The buried insulating film 129 is in contact with the gap fill insulating film 125 and/or the gap fill conductive film 127. The first material film 122, the second insulating film 123, the second material film 124, the gap fill insulating film 125, and the gap fill conductive film 127 are spaced apart from the first side 100a of the first substrate 100 by the buried insulating film 129. In some embodiments, a part of the first insulating film 121 is interposed between the clement isolation pattern 110 and the buried insulating film 129. For example, the buried insulating film 129 is in contact with an inner wall of the first insulating film 121. Although is the figures show that there is a boundary between the first insulating film 121 and the buried insulating film 129, embodiments are not necessarily limited thereto, and in other embodiments, there is no boundary between the first insulating film 121 and the buried insulating film 129. For example, when the first insulating film 121 and the buried insulating film 129 include the same material, such as a silicon oxide film, there is no boundary between the first insulating film 121 and the buried insulating film 129.

In some embodiments, a depth D12 in a vertical (Z) direction of the buried insulating film 129 is equal to or greater than a depth D11 in the vertical (Z) direction of the element isolation pattern 110, with respect to the first side 100a of the first substrate 100. Although FIG. 6A shows that the depth D12 of the buried insulating film 129 is the same as the depth D11 of the clement isolation pattern 110, embodiments are not necessarily limited thereto, and in other embodiments, the depth D12 of the buried insulating film 129 is greater than the depth D11 of the clement isolation pattern 110.

The buried insulating film 129 includes an insulating material, such as, but not necessarily limited to, at least one of silicon oxide, silicon nitride, silicon oxynitride, or a combination thereof. For example, the buried insulating film 129 includes a silicon oxide film. Although the buried insulating film 129 is shown as being only a single film, embodiments are not necessarily limited thereto, and in other embodiments, the buried insulating film 129 includes multiple films.

In some embodiments, the first portion 120A and/or the second portion 120B of the pixel isolation pattern 120 do not include the gap fill conductive film 127. For example, as shown in FIGS. 3, 4, and 6A, the first portion 120A of the pixel isolation pattern 120 includes a first insulating film 121, a first material film 122, a second insulating film 123, a second material film 124, a gap fill insulating film 125 and a buried insulating film 129. The first insulating film 121, the first material film 122, the second insulating film 123, and the second material film 124 are sequentially stacked on the inner wall of the first trench DT1. The gap fill insulating film 125 fills at least a part of the first trench DT1 that remains after being filled with the first insulating film 121, the first material film 122, the second insulating film 123, and the second material film 124. The buried insulating film 129 separates each of the first material film 122, the second insulating film 123, the second material film 124, and the gap fill insulating film 125 from the first side 100a of the first substrate 100.

In some embodiments, in the first portion 120A and/or the second portion 120B of the pixel isolation pattern 120, each of the first material film 122, the second insulating film 123, and the second material film 124 is in contact with the buried insulating film 129. For example, as shown in FIG. 6A, one end of the first material film 122 adjacent to the first side 100a, one end of the second insulating film 123 adjacent to the first side 100a, and one end of the second material film 124 adjacent to the first side 100a are in contact with the buried insulating film 129, respectively.

In some embodiments, the third portion 120C of the pixel isolation pattern 120 does not include the gap fill insulating film 125. For example, as shown in FIGS. 3, 5, and 6A, the third portion 120C of the pixel isolation pattern 120 includes a first insulating film 121, a first material film 122, a second insulating film 123, a second material film 124, a gap fill conductive film 127, and a buried insulating film 129. The first insulating film 121, the first material film 122, the second insulating film 123, and the second material film 124 are sequentially stacked on the inner wall of the second trench DT2. The gap fill conductive film 127 fills at least a part of the region of the second trench DT2 that remains after being filled with the first insulating film 121, the first material film 122, the second insulating film 123, and the second material film 124. The buried insulating film 129 separates each of the first material film 122, the second insulating film 123, the second material film 124, and the gap fill conductive film 127 from the first side 100a of the first substrate 100.

In some embodiments, in the third portion 120C of the pixel isolation pattern 120, the first material film 122, the second insulating film 123, and the second material film 124 are spaced apart from the buried insulating film 129. For example, as shown in FIG. 6B, a part of the gap fill conductive film 127 is interposed between the first material film 122 and the buried insulating film 129, between the second insulating film 123 and the buried insulating film 129, and between the second material film 124 and the buried insulating film 129.

In some embodiments, in the third portion 120C of the pixel isolation pattern 120, the first material film 122 and the second material film 124 are each in contact with the gap fill conductive film 127. When the first material film 122 and/or the second material film 124 are conductive, the first material film 122 and/or the second material film 124 are electrically connected to the gap fill conductive film 127. Accordingly, a negative (−) bias voltage can be applied to the first material film 122 and/or the second material film 124. Further, a negative (−) bias voltage can be applied over the entire pixel isolation pattern 120, which includes the first portion 120A, the second portion 120B, and the third portion 120C.

In some embodiments, a distance D21 that separates the second material film 124 of the third portion 120C from the buried insulating film 129 is from about 10 nm to about 500 nm. For example, the distance D21 that separates the second material film 124 of the third portion 120C from the buried insulating film 129 is from about 100 nm to about 300 nm.

In some embodiments, the gap fill conductive film 127 of the third portion 120C includes a first curved surface 127S1 in contact with the first material film 122, the second insulating film 123, and the second material film 124. The first curved surface 127S1 is convex upward toward the first material film 122, the second insulating film 123, and the first material film 122.

A first circuit element CC may be formed on the first side 100a of the first substrate 100. The first circuit element CC includes various transistors that process electrical signals generated by each of the unit pixels G1 to G8, R1 to R4, and B1 to B4 inside the first substrate 100. For example, the first circuit element CC may include the transfer transistor TX, the reset transistor RX, the drive transistor DX, and/or the selection transistor SX, etc., described above with respect to FIG. 2.

In some embodiments, the first circuit element CC includes a vertical transfer transistor. For example, as shown in FIG. 4, a part of the transfer transistor TX of the first circuit element CC extends into the first substrate 100 toward the photoelectric conversion region 101. Such a transfer transistor TX contributes to a higher integration of image sensors by reducing the area of a unit pixel.

The first wiring structure 140 is formed on the first side 100a of the first substrate 100. The first wiring structure 140 includes a plurality of wiring patterns. For example, the first wiring structure 140 includes a first inter-wiring insulating film 142 on the first side 100a, and a first wiring pattern 144 in the first inter-wiring insulating film 142. In FIGS. 4 and 5, embodiments are not necessarily limited to the number of layers, placement, etc., of the first wiring pattern 144 shown therein. The first wiring structure 140 is electrically connected to the impurity region 102 and/or the first circuit clement CC, and can transmit and/or receive electrical signals to and/or from each of the unit pixels G1 to G8, R1 to R4, and B1 to B4.

The surface insulating film 150 is formed on the second side 100b of the first substrate 100. The surface insulating film 150 conformally extends along the second side 100b of the first substrate 100. The surface insulating film 150 includes an insulating material, such as, but not necessarily limited to, at least one of silicon oxide, silicon nitride, silicon oxynitride, aluminum oxide, hafnium oxide, or combinations thereof.

The surface insulating film 150 is an antireflection film, and prevents reflection of light incident on the second side 100b, which is the photo-receiving surface. Accordingly, the photo-receiving rate of the photoelectric conversion region 101 is increased. In some embodiments, the surface insulating film 150 is a flattening film, and contributes to forming a color filter 180, a micro lens 190, etc., to be described below at a uniform height.

In some embodiments, the surface insulating film 150 includes multiple films. For example, unlike the example shown, the surface insulating film 150 includes an aluminum oxide film, a hafnium oxide film, a silicon oxide film, a silicon nitride film, and a hafnium oxide film that are sequentially stacked on the second side 100b of the first substrate 100.

The grid pattern 160 is formed on the surface insulating film 150. The grid pattern 160 has a lattice shape in a plan view, such as in the XY plane. For example, the grid pattern 160 overlaps at least a part of the pixel isolation pattern 120 in the fourth direction Z.

In some embodiments, the grid pattern 160 includes a first grid pattern 162 and a second grid pattern 164. The first grid pattern 162 and the second grid pattern 164 arc sequentially stacked on the surface insulating film 150.

The first grid pattern 162 includes, for example, but is not necessarily limited to, at least one of titanium (Ti), titanium nitride (TiN), tantalum (Ta), tantalum nitride (TaN), tungsten (W), aluminum (Al), copper (Cu), or combinations thereof. The first grid pattern 162 pattern prevents electric charges generated by ESD (electrostatic discharge), etc., from accumulating on the surface of the first substrate 110, such as the second face 110b, to effectively prevent an ESD bruise defect.

The second grid pattern 164 includes a low refractive index material that has a lower refractive index than silicon (Si). For example, the second grid pattern 164 includes, but is not necessarily limited to, at least one of silicon oxide, aluminum oxide, tantalum oxide, or combinations thereof. The second grid pattern 164 increases the light collection efficiency of each of the unit pixels G1 to G8, R1 to R4, and B1 to B4, by refracting or reflecting light obliquely incident on the second side 100b, which is a photo-receiving surface.

A first protective film 166 is formed on the surface insulating film 150 and the grid pattern 160. The first protective film 166 conformally extends along the profiles of the surface insulating film 150 and the grid pattern 160. The first protective film 166 prevents damage to the surface insulating film 150 and the grid pattern 160. The first protective film 166 includes, for example, but is not necessarily limited to, aluminum oxide (AlO).

The color filter 180 is formed on the first protective film 166. The color filter 180 may have various colors depending on the unit pixel. For example, the color filter 180 may include a red filter, a green filter, a blue filter, a yellow filter, a magenta filter, and a cyan filter, and may further include a white filter.

In some embodiments, unit pixels included in each pixel group share a color filter of the same color. Furthermore, adjacent pixel groups have color filters of different colors. For example, the plurality of pixel groups include color filters 180 arranged in the form of a Bayer pattern. For example, each of the first pixel group G1 to G4 and the fourth pixel group G5 to G8 overlaps the green G color filter 180, the second pixel groups R1 to R4 overlap the red R color filter 180, and the third pixel groups B1 to B4 overlap the blue B color filter 180.

The micro lens 190 is formed on the color filter 180. The micro lens 190 has a convex shape, and has a predetermined radius of curvature. Accordingly, the micro lens 190 collects light that enters the photoelectric conversion region 101. The micro lens 190 includes, for example, but is not necessarily limited to, a light-transmitting resin.

In some embodiments, unit pixels in each pixel group share one micro lens 190. For example, the micro lens 190 corresponds to each pixel group. Accordingly, each pixel group provides an auto-focus (AF) function. For example, the first pixel groups G1 to G4 provide a phase detection AF (PDAF) function using the divided photoelectric conversion regions 101.

A second protective film 195 is formed on the micro lens 190. The second protective film 195 conformally extends along the surface of the micro lens 190. The second protective film 195 includes, for example, but is not necessarily limited to, an inorganic oxide film such as at least one of a silicon oxide film, a titanium oxide film, a zirconium oxide film or a hafnium oxide film. For example, the second protective film 195 includes a low temperature oxide (LTO).

The second protective film 195 protects the micro lens 190. For example, the second protective film 195 protects the micro lens 190 that contains an organic material by including an inorganic oxide film. Further, the second protective film 195 increases the quality of the image sensor by increasing the light collection efficiency of the micro lens 190. For example, the second protective film 195 reduces reflection, refraction, scattering, etc., of incident light that reaches the space between the micro lenses 190 by filling the space between the micro lenses 190.

To increase the performance of image sensors, pixel isolation patterns that include conductive materials, such as impurity-doped polysilicon, have been proposed. For example, the dark current characteristics of the image sensor can be improved by applying a negative (−) bias voltage to the pixel isolation pattern that includes the conductive material. However, as a pixel isolation pattern that includes silicon (Si) as a conductive material has a relatively large refractive index, the image sensor is vulnerable to optical cross-talk between adjacent unit pixels.

An image sensor according to some embodiments reduces an optical cross-talk between adjacent unit pixels by using the pixel isolation pattern 120 that includes the gap fill insulating film 125. For example, as described above, the first portion 120A and/or the second portion 120B, or the first trench DT1 of the pixel isolation trench DT, of the pixel isolation pattern 120 that have a relatively narrow width, such as the first width W1, are filled with a gap fill insulating film 125 that has a relatively low refractive index. The first portion 120A and/or second portion 120B provide a wider low refractive index region to the pixel isolation pattern 120. Accordingly, the light collection efficiency of each of the unit pixels G1 to G8, R1 to R4, and B1 to B4 is increased, and an image sensor that has increased performance is provided.

In addition, an image sensor according to some embodiments provides an electrical connection over the entire pixel isolation pattern 120, using the first material film 122, the second material film 124, and the gap fill conductive film 127. For example, as described above, the third portion 120C of the pixel isolation pattern 120, or the second trench DT2 of the pixel isolation trench DT, that has a relatively wide width, such as the second width W2, is filled with the gap fill conductive film 127 that includes a conductive material. Further, since the third portion 120C of the pixel isolation pattern 120 is electrically connected to the conductive first material film 122 and/or second material film 124, a negative (−) bias voltage can be applied over the entire pixel isolation pattern 120.

In addition, an image sensor according to some embodiments further reduces optical cross-talk between adjacent unit pixels by using the pixel isolation pattern 120 that includes the second insulating film 123. For example, as described above, the second insulating film 123 that has a relatively low refractive index is interposed between the first material film 122 and the second material film 124. Such a second insulating film 123 provides an additional low refractive index region between the first substrate 100 and the gap fill conductive film 127 in the third portion 120C of the pixel isolation pattern 120, or the second trench DT2 of the pixel isolation trench DT. Accordingly, the light collection efficiency of each of the unit pixels G1 to G8, R1 to R4, and B1 to B4 is increased, and an image sensor that has increased performance is provided.

Referring to FIGS. 3 to 5 and 6B to 6D, in an image sensor according to some embodiments, the first portion 120A and/or the second portion 120B of the pixel isolation pattern 120 includes a gap fill conductive film 127.

For example, as shown in FIGS. 6B to 6D, the first portion 120A of the pixel isolation pattern 120 includes a first insulating film 121, a first material film 122, a second insulating film 123, a second material film 124, a gap fill insulating film 125, a gap fill conductive film 127, and a buried insulating film 129. The gap fill conductive film 127 of the first portion 120A and/or the second portion 120B is interposed between the gap fill insulating film 125 and the buried insulating film 129.

Referring to FIG. 6B, in an image sensor according to some embodiments, the gap fill conductive film 127 of the first portion 120A and/or the second portion 120B is in contact with the inner wall of the second material film 124. For example, the first material film 122, the second insulating film 123, and the second material film 124 are in contact with the buried insulating film 129 in the first portion 120A and/or the second portion 120B of the pixel isolation pattern 120.

In some embodiments, the distance D23 that separates the gap fill insulating film 125 of the first portion 120A and/or the second portion 120B from the buried insulating film 129 is from about 100 nm to about 1000 nm. For example, the distance D23 that separates the gap fill insulating film 125 of the first portion 120A and/or the second portion 120B from the buried insulating film 129 is from about 300 nm to about 700 nm. In some embodiments, the distance D23 that separates the gap fill insulating film 125 of the first portion 120A and/or the second portion 120B from the buried insulating film 129 is equal to or greater than the distance D21 that separates the second material film 124 of the third portion 120C from the buried insulating film 129.

In some embodiments, the gap fill conductive film 127 of the first portion 120A and/or the second portion 120B includes a second curved surface 127S2 that is in contact with the gap fill insulating film 125. The second curved surface 127S2 is convex upward toward the gap fill insulating film 125.

Referring to FIG. 6C, in an image sensor according to some embodiments, the gap fill conductive film 127 of the first portion 120A and/or the second portion 120B is in contact with the inner wall of the first material film 122. For example, in the first portion 120A and/or the second portion 120B of the pixel isolation pattern 120, the first material film 122 is in contact with the buried insulating film 129, and the second insulating film 123 and the second material film 124 are spaced apart from the buried insulating film 129 by the gap fill conductive film 127.

In some embodiments, a distance D22 that separates the second material film 124 of the first portion 120A and/or the second portion 120B from the buried insulating film 129 is from about 10 nm to about 500 nm. For example, the distance D22 that separates the second material film 124 of the first portion 120A and/or the second portion 120B from the buried insulating film 129 is from about 100 nm to about 300 nm. In some embodiments, the distance D22 that separates the second material film 124 of the first portion 120A and/or the second portion 120B from the buried insulating film 129 is equal to or less than the distance D21 that separates the second material film 124 of the third portion 120C from the buried insulating film 129.

In some embodiments, the gap fill conductive film 127 of the first portion 120A and/or the second portion 120B include a second curved surface 127S2 that is in contact with the second insulating film 123, the second material film 124, and the gap fill insulating film 125. The second curved surface 127S2 is convex upward toward the second insulating film 123, the second material film 124, and the gap fill insulating film 125.

Referring to FIG. 6D, in an image sensor according to some embodiments, the gap fill conductive film 127 of the first portion 120A and/or the second portion 120B is in contact with the inner wall of the first insulating film 121. For example, in the first portion 120A and/or the second portion 120B of the pixel isolation pattern 120, the first material film 122, the second insulating film 123, and the second material film 124 are spaced apart from the buried insulating film 129 by the gap fill conductive film 127.

In some embodiments, the gap fill conductive film 127 of the first portion 120A and/or the second portion 120B includes a second curved surface 127S2 that is in contact with the first material film 122, the second insulating film 123, the second material film 124, and the gap fill insulating film 125. The second curved surface 127S2 is convex upward toward the first material film 122, the second insulating film 123, the second material film 124, and the gap fill insulating film 125.

Referring to FIG. 6E, in an image sensor according to some embodiments, the first portion 120A and/or the second portion 120B of the pixel isolation pattern 120 do not include the gap fill insulating film 125.

For example, as shown in FIG. 6E, the first portion 120A of the pixel isolation pattern 120 includes the first insulating film 121, the first material film 122, the second insulating film 123, the second material film 124, the gap fill conductive film 127, and the buried insulating film 129. The first insulating film 121, the first material film 122, the second insulating film 123, and the second material film 124 are sequentially stacked on the inner wall of the first trench DT1. The gap fill conductive film 127 fills at least a part of the region of the first trench DT1 that remains after being filled with the first insulating film 121, the first material film 122, the second insulating film 123, and the second material film 124.

Referring to FIGS. 6F to 6H, in an image sensor according to some embodiments, gap fill insulating film 125 includes a void 125V.

The void 125V is formed in a process of filling the pixel isolation trench DT with the gap fill insulating film 125. The void 125V may be an empty space or air trapped inside the gap fill insulating film 125, or may be a seam formed inside the gap fill insulating film 125.

Referring to FIG. 6G, in an image sensor according to some embodiments, the gap fill conductive film 127 of the first portion 120A and/or the second portion 120B is in contact with the inner wall of the first material film 122 and the inner wall of the second material film 124. For example, in the first portion 120A and/or the second portion 120B of the pixel isolation pattern 120, the first material film 122 is in contact with the buried insulating film 129, and the second insulating film 123 and the second material film 124 are spaced apart from the buried insulating film 129 by the gap fill conductive film 127.

Referring to FIG. 6H, in an image sensor according to some embodiments, the gap fill conductive film 127 of the first portion 120A and/or the second portion 120B is in contact with the inner wall of the first insulating film 121 and the inner wall of the second material film 124. For example, in the first portion 120A and/or the second portion 120B of the pixel isolation pattern 120, the first material film 122, the second insulating film 123, and the second material film 124 are spaced apart from the buried insulating film 129 by the gap fill conductive film 127.

In some embodiments, the distance D22 that separates the second material film 124 of the first portion 120A and/or the second portion 120B from the buried insulating film 129 is equal to or less than the distance D21 that separates the second material film 124 of the third portion 120C from the buried insulating film 129.

In some embodiments, the gap fill conductive film 127 of the first portion 120A and/or the second portion 120B includes a third curved surface 127S3 that is in contact with the second insulating film 123. The third curved surface 127S3 is convex upward toward the second insulating film 123.

In some embodiments, the distance D23 that separates the gap fill insulating film 125 of the first portion 120A and/or the second portion 120B from the buried insulating film 129 is equal to or greater than the distance D21 that separates the second material film 124 of the third portion 120C from the buried insulating film 129.

In some embodiments, the gap fill conductive film 127 of the first portion 120A and/or the second portion 120B include a fourth curved surface 127S4 that is in contact with the gap fill insulating film 125. The fourth curved surface 127S4 is convex upward toward the gap fill insulating film 125.

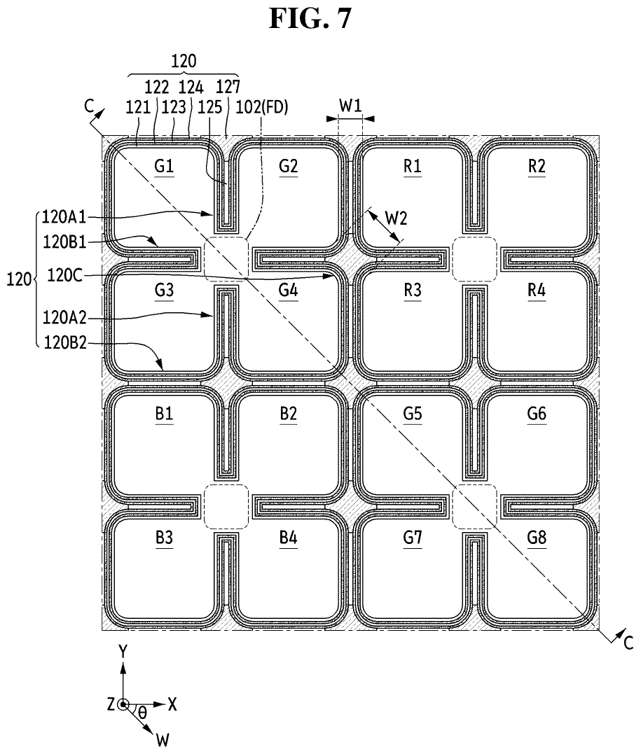

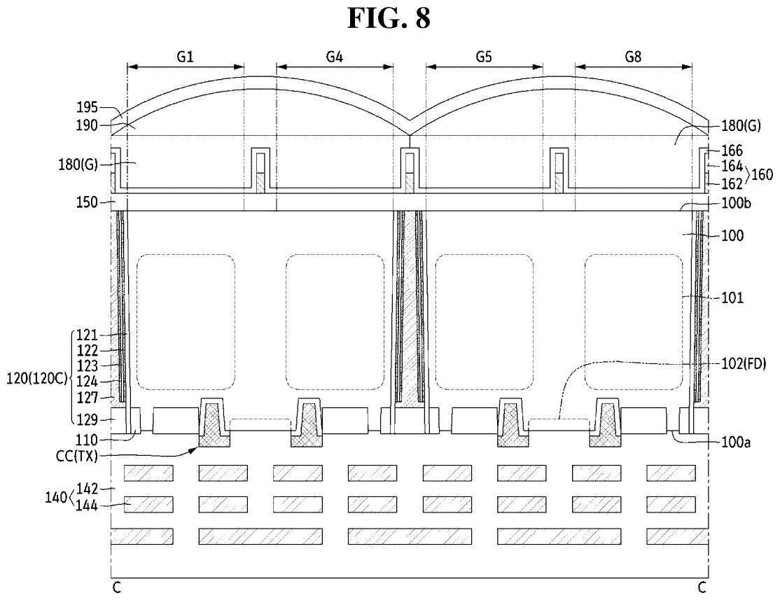

FIG. 7 is a plan view of a pixel array of an image sensor according to some embodiments. FIG. 8 is a schematic cross-sectional view taken along line C-C of FIG. 7. For convenience of explanation, repeated descriptions of components described above using FIGS. 1 to 6 may be summarized or omitted.

Referring to FIGS. 7 and 8, in an embodiment, the pixel isolation pattern 120 includes a region in which centers of adjacent unit pixels are cut in each pixel group. For example, the pixel isolation pattern 120 includes a first separation part 120A1, a second separation part 120A2, a third separation part 120B1, and a fourth separation part 120B2 that define unit pixels of the first pixel group G1 to G4.

The first separation part 120A1 and the second separation part 120A2 are arranged along the second direction Y. The first separation part 120A1 and the second separation part 120A2 are spaced apart from each other in the second direction Y. The first separation part 120A1 extends along the second direction Y, and separates unit pixels, such as the first unit pixel G1 and the second unit pixel G2, that are adjacent to each other in the first direction X. The second separation part 120A2 extends along the second direction Y, and separates unit pixels, such as the third unit pixel G3 and the fourth unit pixel G4, that are adjacent to each other in the first direction X.

The third separation part 120B1 and the fourth separation part 120B2 are arranged along the first direction X. The third separation part 120B1 and the fourth separation part 120B2 are spaced apart in the first direction X. The third separation part 120B1 extends along the first direction X, and separates unit pixels, such as the first unit pixel G1 and the third unit pixel G3, that are adjacent to each other in the second direction Y. The fourth separation unit 120B2 extends along the first direction X, and separates unit pixels, such as the second unit pixel G2 and the fourth unit pixel G4, that are adjacent to each other in the second direction Y.

In some embodiments, the floating diffusion region FD is interposed between the first separation part 120A1 and the second separation part 120A2, and between the third separation part 120B1 and the fourth separation part 120B2. In some embodiments, adjacent unit pixels of each pixel group share a floating diffusion region FD. For example, the floating diffusion region FD of the first pixel groups G1 to G4 is disposed at the center of the first pixel groups G1 to G4. The first unit pixel G1, the second unit pixel G2, the third unit pixel G3, and the fourth unit pixel G4 share such a floating diffusion region FD.

In some embodiments, the second width W2 of the third portion 120C is greater than the first width W1 of each of the first to fourth separation parts 120A1, 120A2, 120B1, and 120B1.

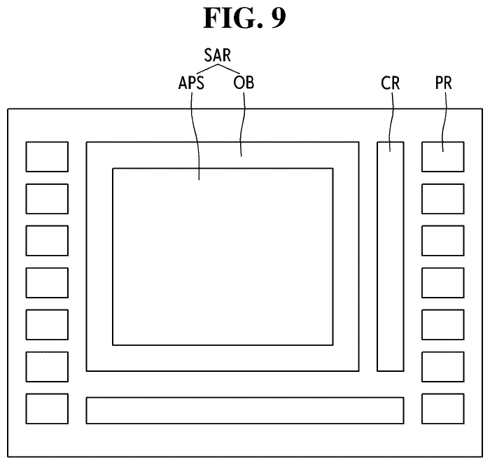

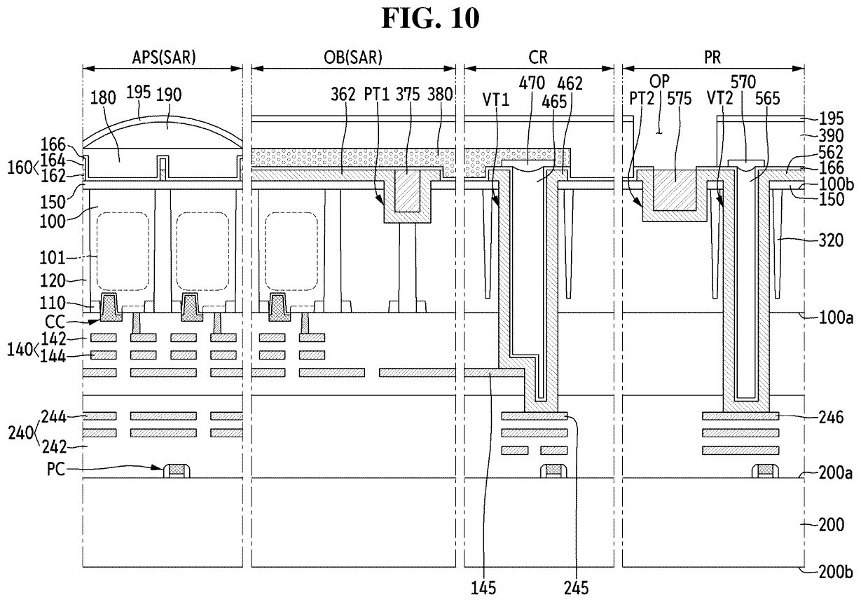

FIG. 9 is a schematic layout diagram of an image sensor according to some embodiments. FIG. 10 is a schematic cross-sectional view of an image sensor of FIG. 9. For convenience of explanation, repeated descriptions of components described above using FIGS. 1 to 8 may be summarized or omitted.

Referring to FIGS. 9 and 10, an image sensor according to some embodiments includes a sensor array region SAR, a connection region CR, and a pad region PR.

The sensor array region SAR includes a region that corresponds to the active pixel sensor array 1 of FIG. 1. For example, a plurality of unit pixels that are two-dimensionally arranged, e.g., in the form of a matrix, are formed in the sensor array region SAR.

The sensor array region SAR includes a photo-receiving region APS and a photo-shielding region OB. Active pixels that receive light and generate active signals are disposed in the photo-receiving region APS. Optical black pixels that generate optical black signals by shielding the light are arranged in the photo-shielding region OB. The photo-shielding region OB is formed, for example, along the periphery of the photo-receiving region APS, but embodiments are not necessarily limited thereto.

In some embodiments, the photoelectric conversion region 101 is formed inside a part of the photo-shielding region OB, and is not formed inside another part of the photo-shielding region OB. For example, the photoelectric conversion region 101 is formed inside a part of the photo-shielding region OB adjacent to the photo-receiving region APS, but is not formed inside a part of the photo-shielding region OB spaced apart from the photo-receiving region APS.

In some embodiments, dummy pixels are formed in the photo-receiving region APS adjacent to the photo-shielding region OB.

The connection region CR is formed around the sensor array region SAR. The connection region CR is formed on one side of the sensor array region SAR, but embodiments are not necessarily limited thereto. Wirings are formed in the connection region CR that transmit and/or receive electrical signals from the sensor array region SAR.

The pad region PR is formed around the sensor array region SAR. The pad region PR is formed adjacent to the edge of the image sensor according to some embodiments, but embodiments are not necessarily limited thereto. The pad region PR is connected to an external device, etc., and transmits and/or receives electrical signals between an image sensor according to some embodiments and an external device.

Although the connection region CR is shown as being interposed between the sensor array region SAR and the pad region PR, embodiments are not necessarily limited thereto. In other embodiments, the placement of the sensor array region SAR, the connection region CR, and the pad region PR varies as necessary.

The first wiring structure 140 includes a first wiring pattern 144 in the sensor array region SAR and a second wiring pattern 145 in the connection region CR. The first wiring pattern 144 is electrically connected to the unit pixels of the sensor array region SAR. At least a part of the second wiring pattern 145 is electrically connected to at least a part of the first wiring pattern 144. Accordingly, the second wiring pattern 145 is electrically connected to the unit pixel of the sensor array region SAR.

An image sensor according to some embodiments includes a second substrate 200 and a second wiring structure 240.

The second substrate 200 may be bulk silicon or silicon-on-insulator (SOI). The second substrate 200 may be a silicon substrate, or may include other materials, such as at least one of silicon germanium, indium antimonide, lead telluride, indium arsenide, indium phosphide, gallium arsenide or gallium antimonide. In some embodiments, the second substrate 200 includes an epitaxial layer formed on a base substrate.

The second substrate 200 includes a third side 200a and a fourth side 200b that are opposite to each other. In an embodiment to be described below, the third side 200a may be called a front side of the second substrate 200, and the fourth side 200b may be called a back side of the second substrate 200. In some embodiments, the third side 200a of the second substrate 200 is opposite to the first side 100a of the first substrate 100.

A second circuit element PC is formed on the third side 200a of the second substrate 200. The second circuit element PC is electrically connected to the sensor array region SAR, and transmits and/or receives electrical signals to and/or from each unit pixel of the sensor array region SAR. For example, the second circuit element PC includes electronic components that constitute one or more of the row decoder 2, the row driver 3, the column decoder 4, the timing generator 5, the correlated double sampler 6, the analog-to-digital converter 7 or the I/O buffer 8 of FIG. 1.

The second wiring structure 240 is formed on the third side 200a of the second substrate 200. For example, the second wiring structure 240 includes a second inter-wiring insulating film, 242 and various wiring patterns 244, 245, and 246 inside the second inter-wiring insulating film 242. The number of layers and placement of the wiring patterns 244, 245, and 246 shown in FIG. 10 are examples, and embodiments are not necessarily limited thereto.

At least some of the wiring patterns 244, 245, and 246 of the second wiring structure 240 are connected to the second circuit element PC. In some embodiments, the second wiring structure 240 includes a third wiring pattern 244 in the sensor array region SAR, a fourth wiring pattern 245 in the connection region CR, and a fifth wiring pattern 246 in the pad region PR. In some embodiments, the fourth wiring pattern 245 is an uppermost wiring of the plurality of wirings in the connection region CR, and the fifth wiring pattern 246 is an uppermost wiring of the plurality of wirings in the pad region PR.

The first wiring structure 140 and the second wiring structure 240 are bonded to each other. For example, as shown in FIG. 10, the upper surface of the second wiring structure 240 is attached to the lower surface of the first wiring structure 140. The first wiring structure 140 and the second wiring structure 240 are bonded by, for example, a wafer bonding process, but embodiments are not necessarily limited thereto.

An image sensor according to some embodiments includes a first connection structure 362, a second connection structure 462, and a third connection structure 562.

The first connection structure 362 is formed inside the photo-shielding region OB. The first connection structure 362 is formed on the surface insulating film 150 of the photo-shielding region OB. The first connection structure 362 is in contact with a part of the pixel isolation pattern 120. For example, a first pad trench PT1 that exposes the pixel isolation pattern 120 is formed inside the first substrate 100 and the surface insulating film 150 of the photo-shielding region OB. The first connection structure 362 is formed in the first pad trench PT1, and is in contact with the pixel isolation pattern 120 of the photo-shielding region OB. In some embodiments, the first connection structure 362 extends conformally along the profiles of the side surface and the lower surface of the first pad trench PT1.

The first connection structure 362 includes, for example, but is not necessarily limited to, at least one of titanium (Ti), titanium nitride (TiN), tantalum (Ta), tantalum nitride (TaN), tungsten (W), aluminum (Al), copper (Cu) or a combination thereof.

In some embodiments, the first connection structure 362 is electrically connected to a conductive material of the pixel isolation pattern 120, such as the first material film 122, the second material film 124 and/or the gap fill conductive film 127 of FIGS. 3 to 5, and applies a negative (−) bias voltage.

In some embodiments, a first pad 375 that fills the first pad trench PTI is formed on the first connection structure 362. The first pad 375 includes, for example, but is not necessarily limited to, at least one of tungsten (W), copper (Cu), aluminum (Al), gold (Au), silver (Ag), or alloys thereof.

In some embodiments, the first protective film 166 covers the first connection structure 362 and the first pad 375. For example, the first protective film 166 extends conformally along the profiles of the first connection structure 362 and the first pad 375.

The second connection structure 462 is formed inside the connection region CR. The second connection structure 462 is formed on the surface insulating film 150 of the connection region CR. The second connection structure 462 electrically connects the first wiring structure 140 and the second wiring structure 240. For example, a first via trench VT1 that exposes the second wiring pattern 145 and the fourth wiring pattern 245 is formed inside the connection region CR. The first via trench VT1 penetrates through the surface insulating film 150 and into the first substrate 100. The second connection structure 462 is formed in the first via trench VT1, and connects the second wiring pattern 145 and the fourth wiring pattern 245. In some embodiments, the second connection structure 462 extends conformally along the profiles of the side surface and the lower surface of the first via trench VT1.

The second connection structure 462 includes, for example, but is not necessarily limited to, at least one of titanium (Ti), titanium nitride (TiN), tantalum (Ta), tantalum nitride (TaN), tungsten (W), aluminum (Al), copper (Cu) or a combination thereof. In some embodiments, the second connection structure 462 is formed at the same level as the first connection structure 362.

In some embodiments, the first protective film 166 covers the second connection structure 462. For example, the first protective film 166 extends along the profile of the second connection structure 462.

In some embodiments, a first filling insulating film 465 that fills the first via trench VT1 is formed on the second connection structure 462 and the first protective film 166. The first filling insulating film 465 includes, for example, but is not necessarily limited to, at least one of silicon oxide, aluminum oxide, tantalum oxide, or combinations thereof.

In some embodiments, a first capping pattern 470 is formed on the first filling insulating film 465. The first capping pattern 470 covers the upper surface of the first filling insulating film 465.

The third connection structure 562 is formed inside the pad region PR. The third connection structure 562 is formed on the surface insulating film 150 of the pad region PR. The third connection structure 562 electrically connects the second wiring structure 240 to an external device, etc. For example, a second pad trench PT2 that penetrates through the surface insulating film 150 is formed inside the first substrate 100 of the pad region PR. The third connection structure 562 is formed inside the second pad trench PT2, and surfaces of the third connection structure 562 in the second pad trench PT2 are exposed. Further, a second via trench VT2 that penetrates through the surface insulating film 150 and exposes the fifth wiring pattern 246 is formed inside the pad region PR. The third connection structure 562 is formed in the second via trench VT2 and is in contact with the fifth wiring pattern 246. In some embodiments, the third connection structure 562 extends conformally along the profiles of the side surface and the lower surface of the second pad trench PT2 and the second via trench VT2.

The third connection structure 562 includes, for example, but is not necessarily limited to, at least one of titanium (Ti), titanium nitride (TiN), tantalum (Ta), tantalum nitride (TaN), tungsten (W), aluminum (Al), copper (Cu) or a combination thereof. In some embodiments, third connection structure 562 is formed at the same level as the first connection structure 362 and the second connection structure 462.

In some embodiments, the first protective film 166 covers portions of the third connection structure 562. For example, the first protective film 166 conformally extends along the profile of the third connection structure 562 in the second via trench VT2, but not in the second pad trench PT2.

In some embodiments, a second filling insulating film 565 that fills the second via trench VT2 is formed on the third connection structure 562 and the first protective film 166. The second filling insulating film 565 includes, for example, but is not necessarily limited to, at least one of silicon oxide, aluminum oxide, tantalum oxide, or combinations thereof. In some embodiments, the second filling insulating film 565 is formed at the same level as the first filling insulating film 465.

In some embodiments, a second pad 575 that fills the second via trench VT2 is formed on the third connection structure 562. The second pad 575 includes, for example, but is not necessarily limited to, at least one of tungsten (W), copper (Cu), aluminum (Al), gold (Au), silver (Ag), or alloys thereof. In some embodiments, second pad 575 is formed at the same level as the first pad 375. In some embodiments, the first protective film 166 exposes the second pad 575.

In some embodiments, a second capping pattern 570 is formed on the second filling insulating film 565. The second capping pattern 570 covers the upper surface of the second filling insulating film 565.

In some embodiments, a substrate isolation pattern 320 is formed inside the first substrate 100. Although the substrate isolation pattern 320 is shown as being formed only around the second connection structure 462 and the third connection structure 562, embodiments are not necessarily limited thereto. For example, in other embodiments, the substrate isolation pattern 320 is also formed around the first connection structure 362. The substrate isolation pattern 320 includes, for example, but is not necessarily limited to, at least one of silicon oxide, silicon nitride, silicon oxynitride, aluminum oxide, hafnium oxide, or combinations thereof.

In some embodiments, the width of the substrate isolation pattern 320 decreases from the second side 100b of the first substrate 100 toward the first side 100a of the first substrate 100. This results from an etching process that forms the substrate isolation pattern 320 that is performed toward the second side 100b of the first substrate 100. For example, the substrate isolation pattern 320 is a BDTI (Backside DTI) formed by a DTI (Deep Trench Isolation) process on the second side 100b of the first substrate 100. In some embodiments, the substrate isolation pattern 320 is spaced apart from the first side 100a of the first substrate 100.

In some embodiments, a photo-shielding filter 380 is formed on the first connection structure 362 and the second connection structure 462. For example, the photo-shielding filter 380 covers at least a part of the first protective film 166 in the photo-shielding region OB and the connection region CR. The photo-shielding filter 380 blocks light that is incident on the first substrate 100.

In some embodiments, a third protective film 390 is formed on the photo-shielding filter 380. For example, the third protective film 390 covers at least a part of the first protective film 166 in the light shielding region OB, the connection region CR, and the pad region PR. In some embodiments, the second protective film 195 extends along the surface of the third protective film 390. The third protective film 390 includes, for example, but is not necessarily limited to, a light-transmitting resin. In some embodiments, the third protective film 390 is formed at the same level as the micro lens 190.

In some embodiments, the second protective film 195 and the third protective film 390 expose the second pad 575. For example, an exposure opening OP that exposes the second pad 575 is formed in the second protective film 195 and the third protective film 390. Accordingly, the second pad 575 can be connected to an external device, etc., and can transmit and/or receive electrical signals between an image sensor according to some embodiments and the external device. For example, the second pad 575 is an I/O pad of an image sensor according to some embodiments.

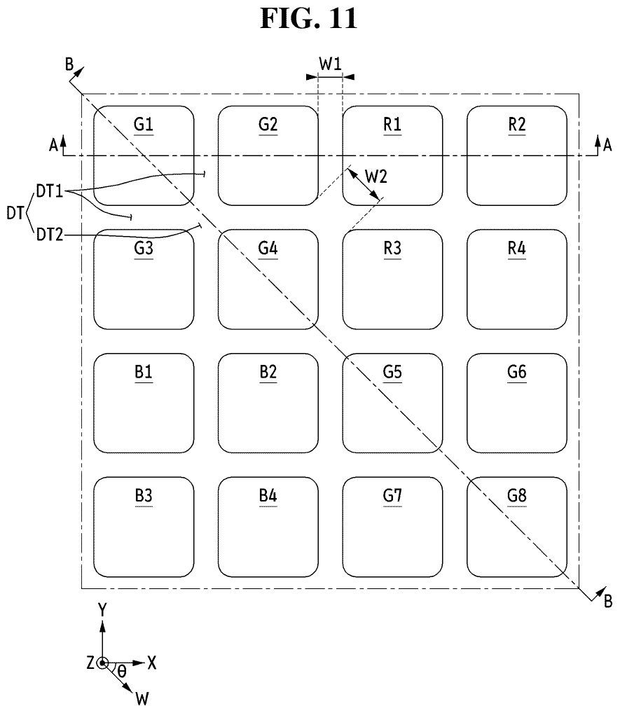

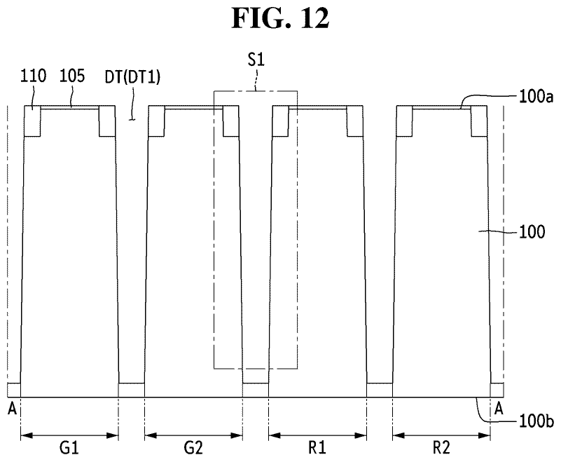

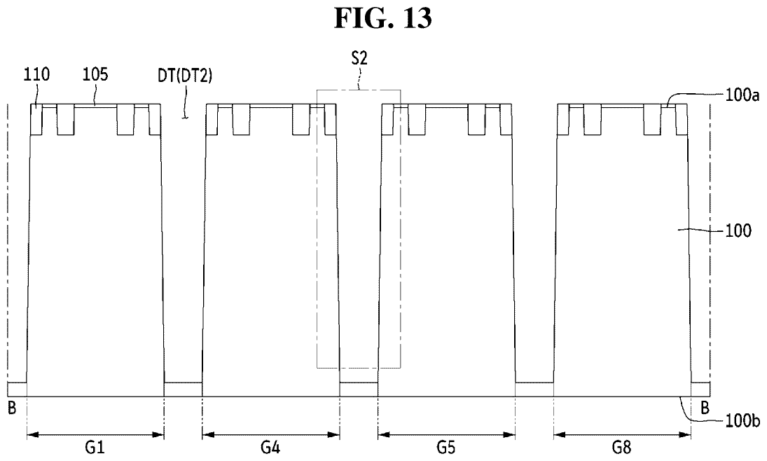

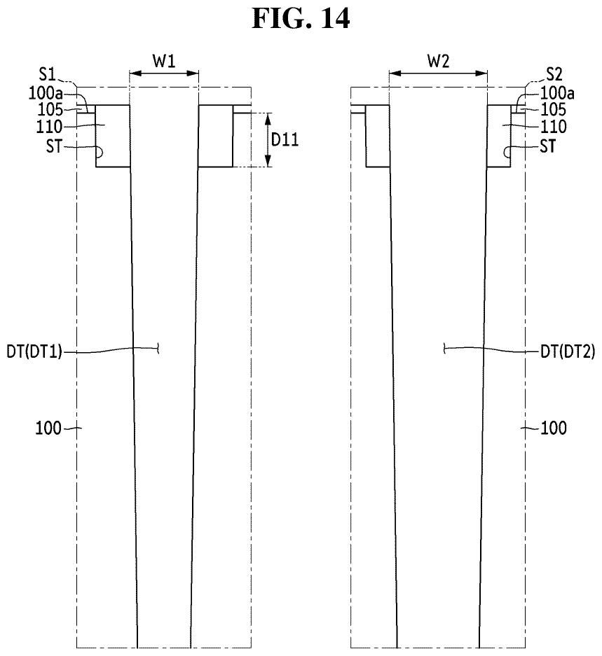

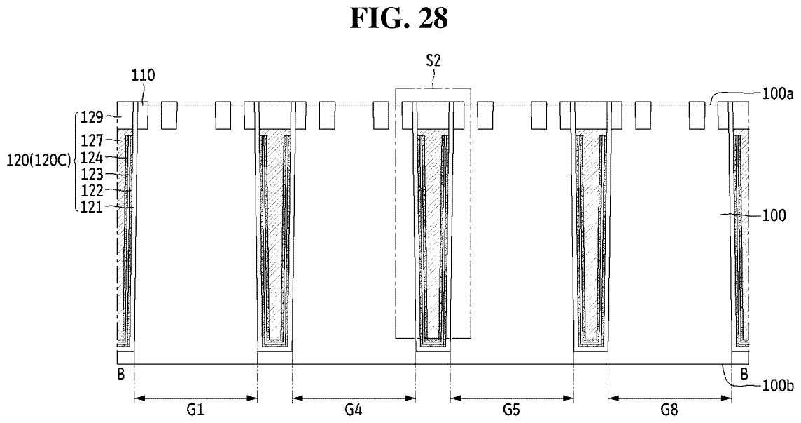

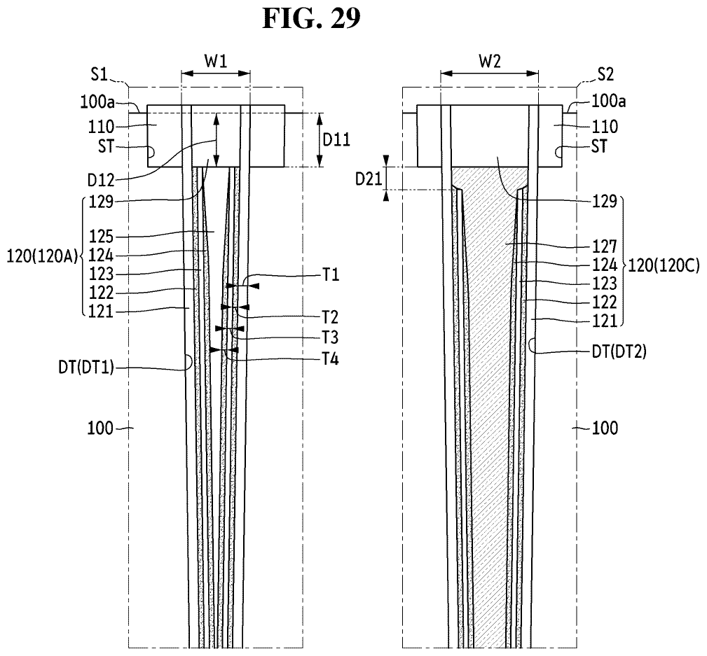

Hereinafter, a method for fabricating an image sensor according to exemplary embodiments will be described with reference to FIGS. 11 to 33.

FIGS. 11 to 33 are intermediate stage diagrams that illustrate a method for fabricating an image sensor according to some embodiments. For convenience of explanation, repeated descriptions of components described above using FIGS. 1 to 10 may be summarized or omitted.

Referring to FIGS. 11 to 14, in an embodiment, the pixel isolation trench DT is formed in the first substrate 100.

For example, a pad insulating film 105 that covers the first side 100a of the first substrate 100 is formed. Subsequently, the element isolation trench ST that defines an active region that includes the first side 100a of the first substrate 100 is formed inside the first substrate 100 and the pad insulating film 105. The element isolation pattern 110 fills at least a part of the element isolation trench ST. Subsequently, the pixel isolation trenches DT that define the plurality of unit pixels G1 to G8, R1 to R4, and B1 to B4 of the first substrate 100 are formed inside the first substrate 100 and the element isolation pattern 110. The pixel isolation trench DT includes a first trench DT1 that has a first width W1, and a second trench DT2 that has a second width W2 greater than the first width W1.

In some embodiments, the pixel isolation trench DT is spaced apart from the second side 100b of the first substrate 100.

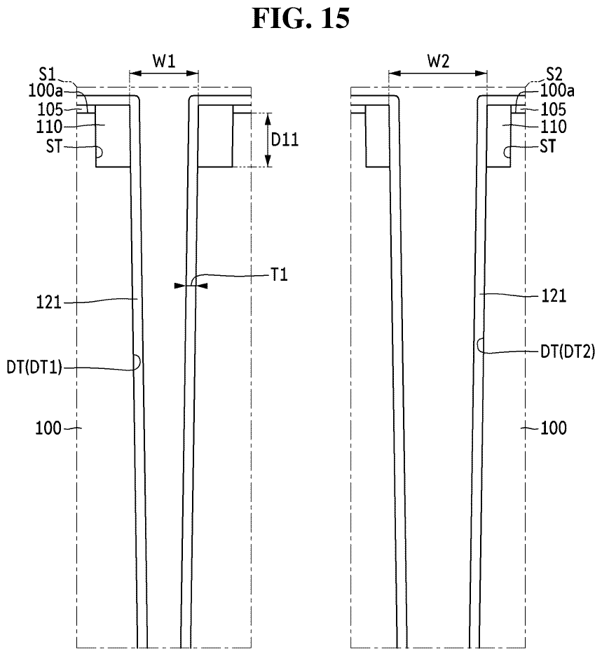

Referring to FIG. 15, in an embodiment, the first insulating film 121 is formed inside the pixel isolation trench DT.

The first insulating film 121 conformally extends along the profile of the inner wall of the pixel isolation trench DT. A thickness T1 of the first insulating film 121 is, for example, from about 1 Å to about 500 Å, or from about 30 Å to about 350 Å. For example, the first insulating film 121 includes a silicon oxide film.

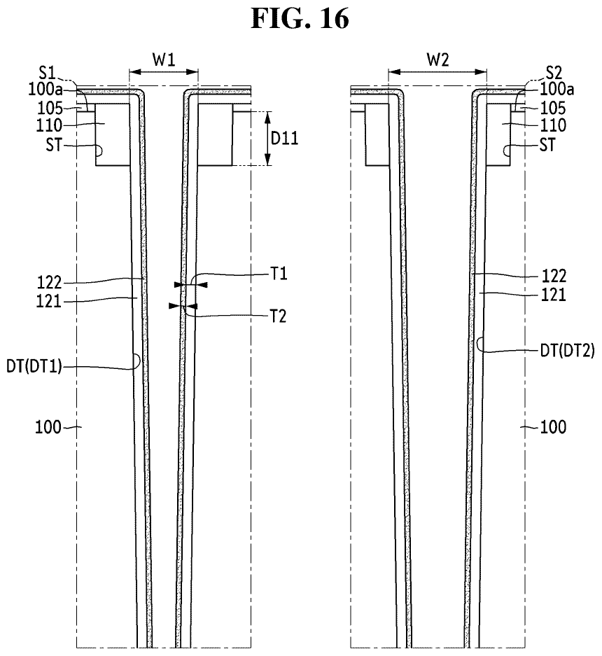

Referring to FIG. 16, in an embodiment, the first material film 122 is formed on the first insulating film 121.

The first material film 122 conformally extends along the profile of the inner wall of the first insulating film 121. A thickness T2 of the first material film 122 is, for example, from about 1 Å to about 500 Å, or from about 10 Å to about 350 Å. For example, the first material film 122 includes a polysilicon film doped with impurities.

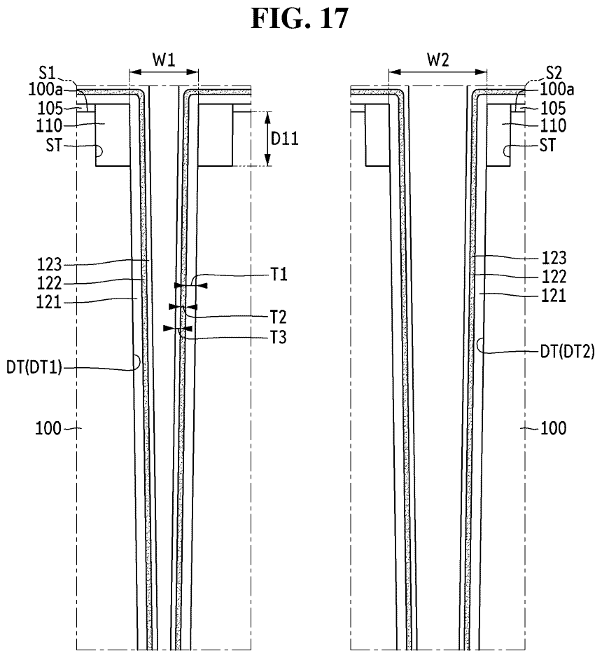

Referring to FIG. 17, in an embodiment, the second insulating film 123 is formed on the first material film 122.

The second insulating film 123 conformally extends along the profile of the inner wall of the first material film 122. A thickness T3 of the second insulating film 123 is, for example, from about 1 Å to about 500 Å, or from about 30 Å to about 350 Å. For example, the second insulating film 123 includes a silicon oxide film.

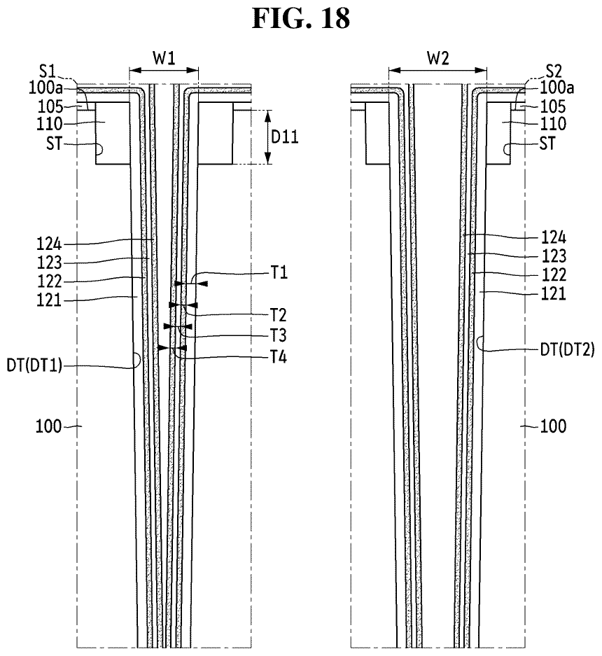

Referring to FIG. 18, in an embodiment, the second material film 124 is formed on the second insulating film 123.

The second material film 124 extends along the inner wall of the second insulating film 123. A thickness T4 of the second material film 124 is, for example, from about 1 Å to about 500 Å, or from about 10 Å to about 350 Å. For example, the second material film 124 includes a polysilicon film doped with impurities.

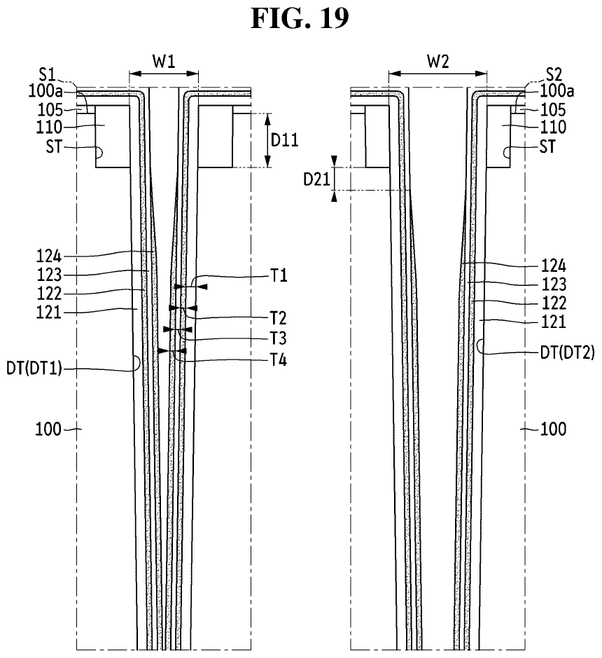

Referring to FIG. 19, in an embodiment, a first etching process is performed on the second material film 124.

For example, after depositing the second material film 124 on the second insulating film 123, the etching process is performed in-situ on the second material film 124. As the first etching process is performed, one end of the second material film 124 adjacent to the first side 100a is formed to have a height equal to or lower than the bottom surface of the element isolation trench ST.

In some embodiments, as the second trench DT2 has a relatively larger width as compared to the first trench DT1, the second material film 124 in the second trench DT2 is etched more excessively than the second material film 124 in the first trench DT1. For example, as shown, the height of the second material film 124 in the second trench DT2 may be lower than the height of the second material film 124 in the first trench DT1. In some embodiments, a distance D21 that separates the second material film 124 in the second trench DT2 from the clement isolation trench ST is from about 10 nm to about 500 nm, or from about 100 nm to about 300 nm.

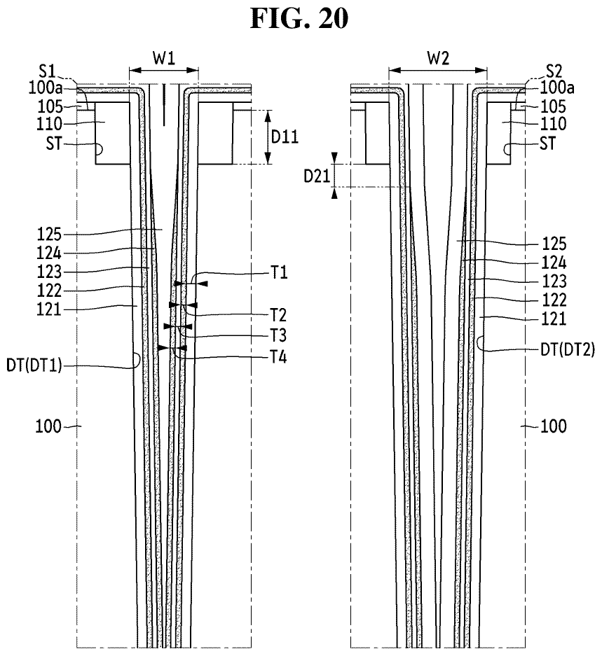

Referring to FIG. 20, in an embodiment, the gap fill insulating film 125 is formed on the second material film 124.

As the second trench DT2 has a relatively larger width as compared to the first trench DT1, the rate at which the first trench DT1 is filled is greater than the rate at which the second trench DT2 is filled.

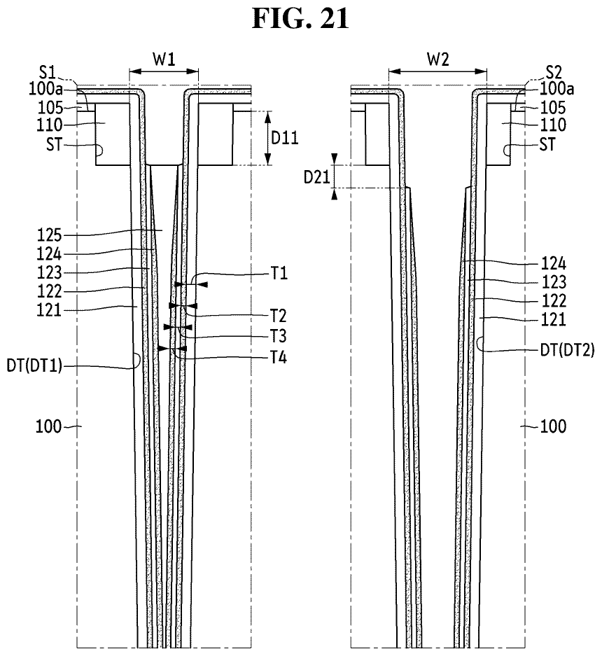

Referring to FIG. 21, in an embodiment, a second etching process is performed on the gap fill insulating film 125.

The second etching process includes, for example, but is not necessarily limited to, a wet etching process that uses hydrogen fluoride (HF). As the second etching process is performed, the gap fill insulating film 125 in the second trench DT2 is removed. Furthermore, as the second etching process is performed, the upper part of the second insulating film 123 exposed from the second material film 124 is removed. As the second trench DT2 has a relatively larger width than the first trench DT1, a part of the gap fill insulating film 125 in the first trench DT1 remains.

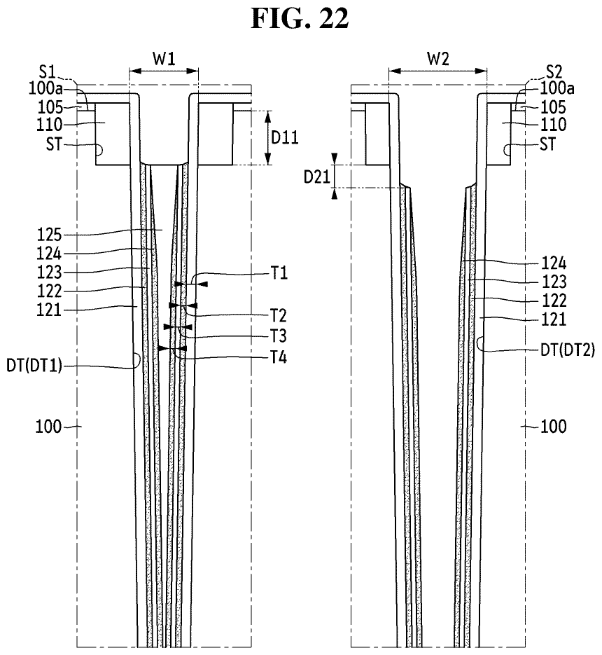

Referring to FIG. 22, in an embodiment, a third etching process is performed on the first material film 122.

The third etching process includes, for example, but is not necessarily limited to, a dry etching process that uses a chlorine (Cl₂) gas. As the third etching process is performed, the upper part of the first material film 122 exposed by the second insulating film 123 is removed.

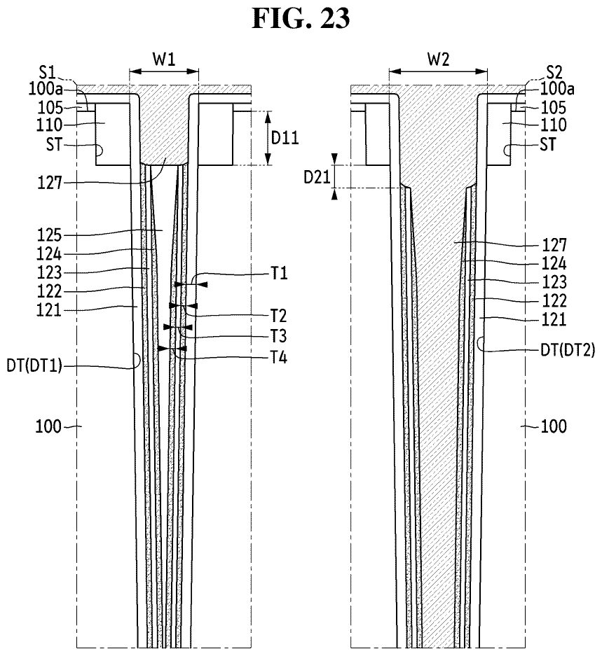

Referring to FIG. 23, in an embodiment, the gap fill conductive film 127 is formed on the first insulating film 121, the first material film 122, the second insulating film 123, the second material film 124, and the gap fill insulating film 125.

The gap fill conductive film 127 fills the region of the pixel isolation trench DT that remains after being filled with the first insulating film 121, the first material film 122, the second insulating film 123, the second material film 124, and the gap fill insulating film 125.

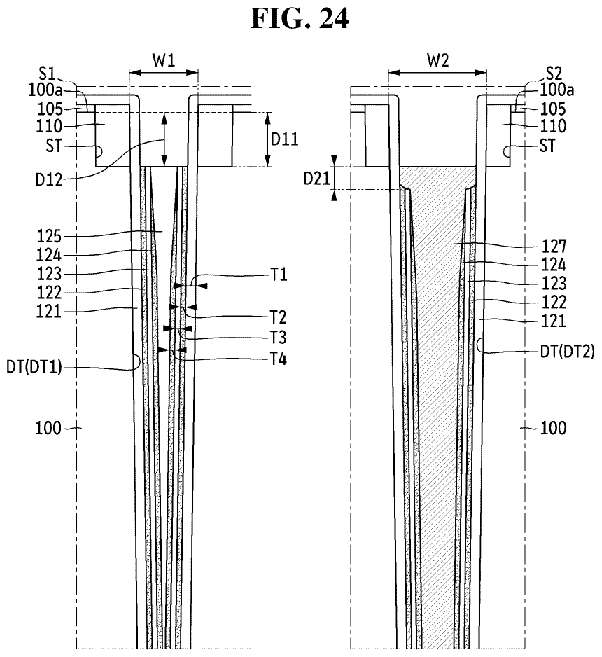

Referring to FIG. 24, in an embodiment, an etch-back process is performed on the gap fill conductive film 127.

As the etch-back process is performed, an upper part of the gap fill conductive film 127 is removed. In some embodiments, the etch-back process is performed such that the upper surface of the gap fill conductive film 127 is coplanar with the bottom surface of the element isolation trench ST, or is formed below the bottom surface. For example, with respect to the first side 100a of the first substrate 100, the depth D12 by which the gap fill conductive film 127 is etched back is equal to or greater than the depth D11 of the element isolation trench ST.

In some embodiments, as the etch-back process is performed, the gap fill conductive film 127 in the first trench DT1 is completely removed.

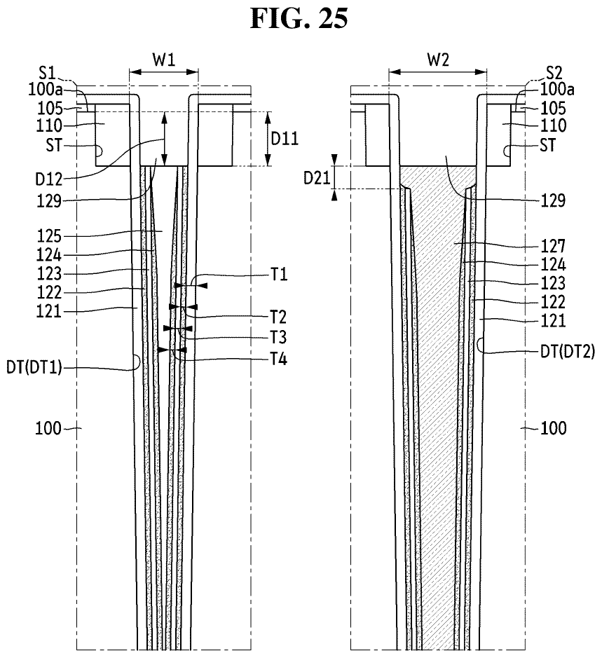

Referring to FIG. 25, in an embodiment, the buried insulating film 129 is formed on the first insulating film 121, the first material film 122, the second insulating film 123, the second material film 124, the gap fill insulating film 125, and the gap fill conductive film 127.

At least a part of the buried insulating film 129 is formed inside the element isolation pattern 110. The buried insulating film 129 is in contact with the gap fill insulating film 125 and/or the gap fill conductive film 127. The first material film 122, the second insulating film 123, the second material film 124, the gap fill insulating film 125, and the gap fill conductive film 127 are each spaced apart from the first side 100a of the first substrate 100 by the buried insulating film 129.

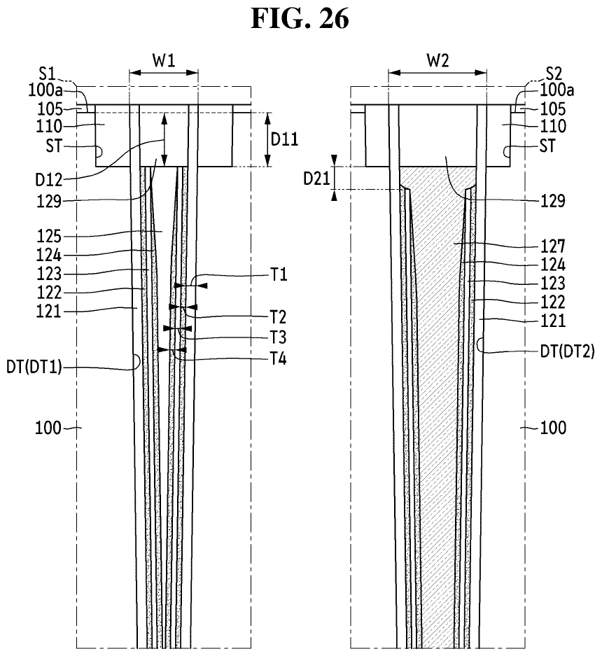

Referring to FIG. 26, in an embodiment, a planarization process is performed on the buried insulating film 129.

The planarization processes includes, for example, but is not necessarily limited to, a chemical mechanical polishing (CMP) process. As the planarization process is performed, the upper surface of the pad insulating film 105, the upper surface of the element isolation pattern 110, the upper surface of the first insulating film 121, and the upper surface of the buried insulating film 129 are formed to be coplanar.

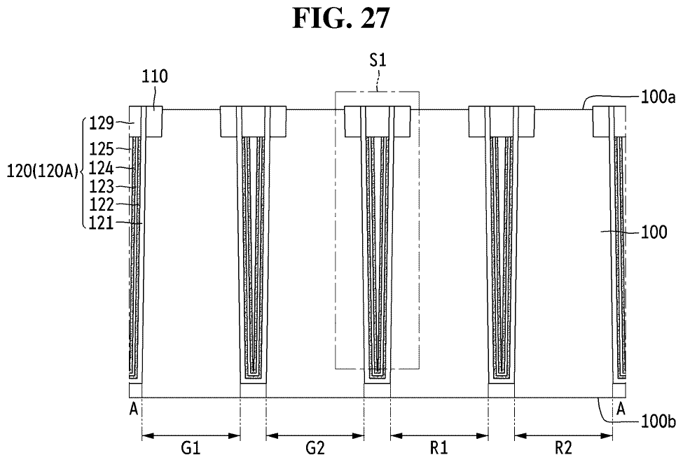

Referring to FIGS. 27 to 29, in an embodiment, the pad insulating film 105 is removed.

As a result, the pixel isolation pattern 120 that includes the first insulating film 121, the first material film 122, the second insulating film 123, the second material film 124, the gap fill insulating film 125, the gap fill conductive film 127 and the buried insulating film 129 is formed inside the first substrate 100 and the element isolation pattern 110.

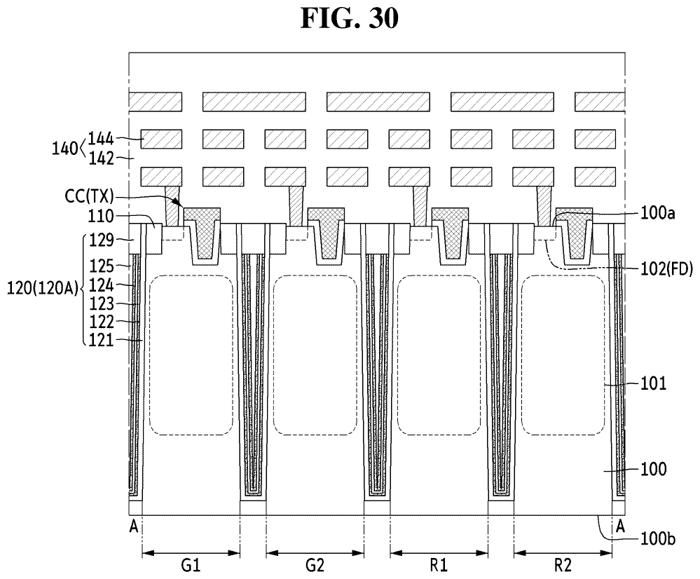

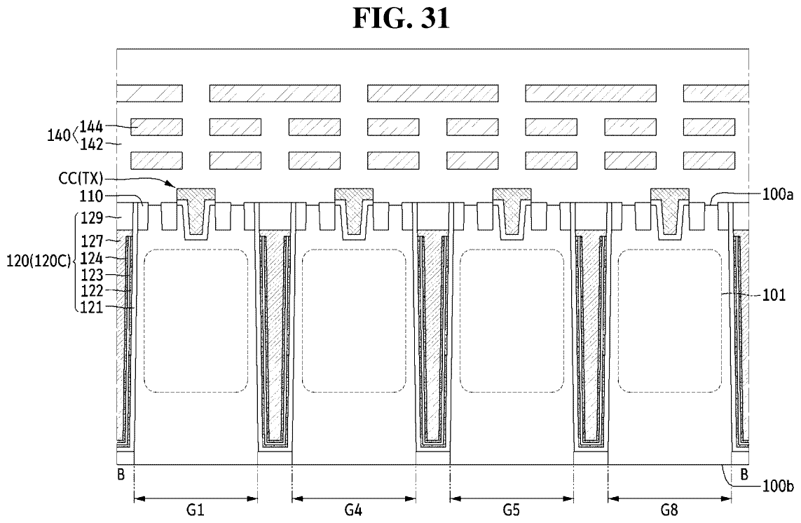

Referring to FIGS. 30 and 31, in an embodiment, the photoelectric conversion region 101 and the impurity region 102 are formed in the first substrate 100, and the first circuit element CC and the first wiring structure 140 are formed on the first side 100a of the first substrate 100.

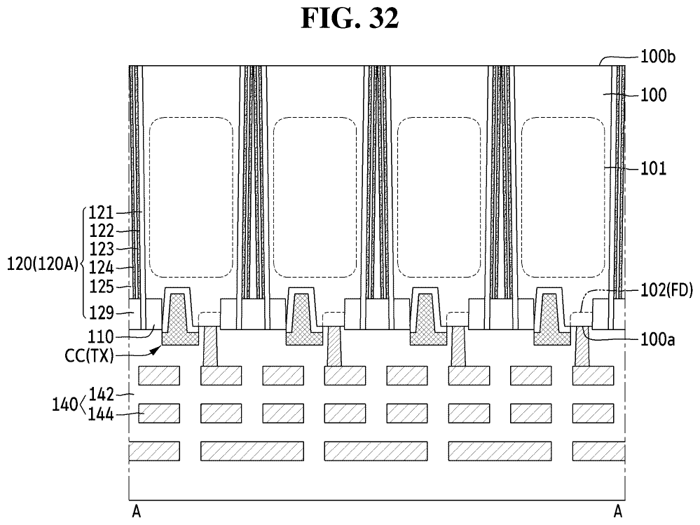

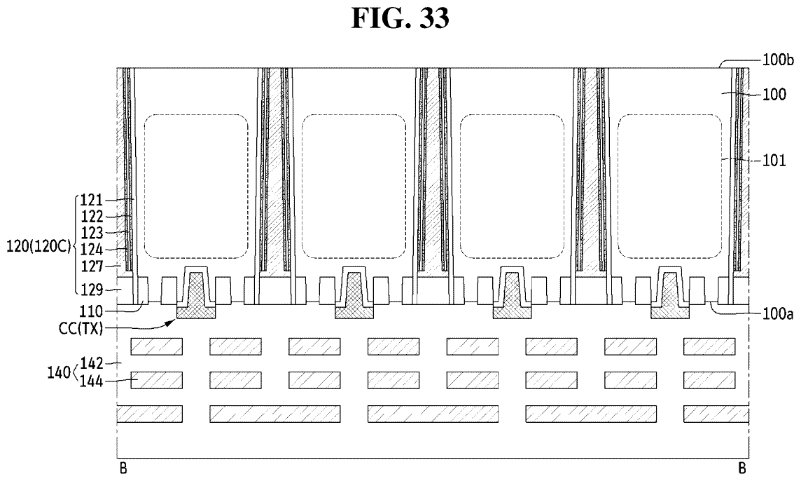

Referring to FIGS. 32 and 33, in an embodiment, a back grinding process is performed on the second side 100b of the first substrate 100.

As the back grinding process is performed, the pixel isolation pattern 120 is exposed on the second side 100b of the first substrate 100. For example, the pixel isolation pattern 120 is provided that completely penetrates the first substrate 100.

Subsequently, referring to FIGS. 4 and 5, the surface insulating film 150, the grid pattern 160, the first protective film 166, the color filter 180 and the micro lens 190 are formed on the first side 100a of the first substrate 100. Accordingly, the image sensor described above using FIGS. 3 to 5 is provided.

While embodiments of the present inventive concept have been particularly shown and described with reference to figures thereof, it will be understood by those of ordinary skill in the art that various changes in form and details may be made therein without departing from the spirit and scope of embodiments of the present inventive concept as defined by the following claims. It is therefore desired that described embodiments be considered in all respects as illustrative and not restrictive, reference being made to the appended claims rather than the foregoing description to indicate the scope of the inventive concept.

What is claimed is:

1. An image sensor, comprising:
a substrate that includes a first side and a second side that are opposite to each other;
a pixel isolation pattern that defines a plurality of unit pixels that are two-dimensionally arranged inside the substrate; and
a photoelectric conversion region inside each of the unit pixels,
wherein the pixel isolation pattern includes a first insulating film, a first material film, a second insulating film, a second material film, and a gap fill conductive film that are sequentially stacked on an inner wall of the substrate,
one end of the first material film adjacent to the first side and one end of the second material film adjacent to the first side are each in contact with the gap fill conductive film, and
the first material film and the second material film include a different material from the first insulating film and the second insulating film.

2. The image sensor of claim 1,
wherein a thickness of the second material film decreases from the second side toward the first side.

3. The image sensor of claim 1,
wherein each of the first insulating film and the second insulating film includes a silicon oxide film.

4. The image sensor of claim 1,
wherein each of the first material film and the second material film includes a polysilicon film doped with impurities.

5. The image sensor of claim 1,
wherein the gap fill conductive film includes a polysilicon film.

6. The image sensor of claim 1, further comprising:
an element isolation pattern inside the substrate, wherein the element isolation pattern is in contact with the first side,
wherein the pixel isolation pattern penetrates the substrate and the element isolation pattern.

7. The image sensor of claim 1,
wherein the pixel isolation pattern further includes a buried insulating film disposed on the gap fill conductive film, and
the gap fill conductive film is spaced apart from the first side by the buried insulating film.

8. The image sensor of claim 7,
wherein a part of the gap fill conductive film is interposed between the first material film and the buried insulating film, between the second insulating film and the buried insulating film, and between the second material film and the buried insulating film.

9. The image sensor of claim 7,
wherein a part of the gap fill conductive film is in contact with an inner wall of the first insulating film.

10. The image sensor of claim 7, further comprising:
an element isolation pattern inside the substrate, wherein the element isolation pattern is in contact with the first side,
wherein a depth with respect to the first side of the buried insulating film is equal to or greater than a depth with respect to the first side of the element isolation pattern.

11. An image sensor, comprising:
a substrate;
a pixel isolation trench that defines a plurality of unit pixels that are two-dimensionally arranged inside the substrate;
a photoelectric conversion region inside each of the unit pixels; and
a pixel isolation pattern that at least partially fills the pixel isolation trench,
wherein the pixel isolation trench includes a first trench that has a first width and a second trench that has a second width greater than the first width,
a first portion of the pixel isolation pattern includes a first insulating film, a first material film, a second insulating film, a second material film, and a gap fill insulating film that are sequentially stacked on an inner wall of the first trench,
a second portion of the pixel isolation pattern includes the first insulating film, the first material film, the second insulating film, the second material film, and a gap fill conductive film that are sequentially stacked on an inner wall of the second trench, and
the first material film and the second material film include a different material from the first insulating film and the second insulating film.

12. The image sensor of claim 11,
wherein the substrate includes a first side and a second side that are opposite to each other,
the second side is a photo-receiving surface on which light is incident, and
one end of the first material film adjacent to the first side and one end of the second material film adjacent to the first side are each in contact with the gap fill conductive film.

13. The image sensor of claim 11,
wherein each of the first insulating film, the second insulating film, and the gap fill insulating film includes a silicon oxide film.

14. The image sensor of claim 11,
wherein each of the first material film and the second material film includes a polysilicon film doped with impurities.

15. The image sensor of claim 11,
wherein the gap fill conductive film includes a polysilicon film.

16. An image sensor, comprising:
a substrate;
a pixel isolation pattern that defines a plurality of unit pixels that are two-dimensionally arranged inside the substrate; and
a photoelectric conversion region inside each of the unit pixels,
wherein the plurality of unit pixels include a first unit pixel, a second unit pixel adjacent to the first unit pixel in a first direction, and a third unit pixel adjacent to the second unit pixel in a second direction that crosses the first direction,
the pixel isolation pattern includes a first portion disposed between the first unit pixel and the second unit pixel, and a second portion disposed between the first unit pixel and the third unit pixel,
the first portion of the pixel isolation pattern includes a first insulating film, a first material film, a second insulating film, a second material film, and a gap fill insulating film that are sequentially stacked on an inner wall of the substrate,
the second portion of the pixel isolation pattern includes the first insulating film, the first material film, the second insulating film, the second material film, and a gap fill conductive film that are sequentially stacked on the inner wall of the substrate,
at least one of the first material film or the second material film is conductive.

17. The image sensor of claim 16,
wherein the substrate includes a first side and a second side that are opposite to each other,
the second side is a photo-receiving surface on which light is incident, and
one end of the first material film adjacent to the first side and one end of the second material film adjacent to the first side are each in contact with the gap fill conductive film.

18. The image sensor of claim 16,
wherein each of the first insulating film, the second insulating film, and the gap fill insulating film includes a silicon oxide film.

19. The image sensor of claim 16,
wherein each of the first material film and the second material film includes a polysilicon film doped with impurities.

20. The image sensor of claim 16,
wherein the gap fill conductive film includes a polysilicon film.
